(19) United States
(12) Patent Application Publication
(10) Pub. No.: US 2023/0072833 A1
(43) Pub. Date: Mar. 9, 2023

(54) SEMICONDUCTOR MEMORY DEVICE

(71) Applicant: Kioxia Corporation, Tokyo (JP)

(72) Inventors: Hiroki MITO, Yokkaichi (JP); Daigo ICHINOSE, Nagoya (JP)

(73) Assignee: Kioxia Corporation, Tokyo (JP)

(21) Appl. No.: 17/578,803

(22) Filed: Jan. 19, 2022

(30) Foreign Application Priority Data
Sep. 7, 2021 (JP) 2021-145550

(51) Int. Cl. G11C 5/06; H01L 27/11519; H01L 27/1157; H01L 27/11551; H01L 27/11524; H01L 27/11565; H01L 27/11578; H01L 23/528

(52) U.S. Cl. CPC G11C 5/06; H01L 27/11519; H01L 27/1157; H01L 27/11551; H01L 27/11524; H01L 27/11565; H01L 27/11578; H01L 23/5283

(57) ABSTRACT

A semiconductor memory device according to an embodiment includes a substrate, a lower interconnect, a source line, word lines, a pillar, a pattern portion, a contact. The source line is provided in a first layer above the lower interconnect. The pattern portion is provided to be separated and insulated from the source line in the first layer. A contact is extending in a first direction, penetrating the pattern portion, and provided on the lower interconnect. A width of the contact in a second direction parallel to a surface of the substrate differs between a portion above a boundary plane that is included in the first layer and is parallel to the surface of the substrate, and a portion below the boundary plane.

### CROSS-REFERENCE TO RELATED APPLICATIONS

This application is based upon and claims the benefit of priority from Japanese Patent Application No. 2021-145550, filed Sep. 7, 2021, the entire contents of which are incorporated herein by reference.

### FIELD

Embodiments described herein relate generally to a semiconductor memory device.

### BACKGROUND

A NAND flash memory capable of storing data in a non-volatile manner is known.

### BRIEF DESCRIPTION OF THE DRAWINGS

FIG. 1 is a block diagram showing an example of an overall configuration of a semiconductor memory device according to an embodiment.

FIG. 2 is a circuit diagram showing an example of a circuit configuration of a memory cell array included in the semiconductor memory device according to the embodiment.

FIG. 3 is a plan view showing an example of a planar layout of the memory cell array included in the semiconductor memory device according to the embodiment.

FIG. 4 is a plan view showing an example of a planar layout of a block group in the memory cell array included in the semiconductor memory device according to the embodiment.

FIG. 5 is a plan view showing an example of a planar layout in a memory area of the memory cell array included in the semiconductor memory device according to the embodiment.

FIG. 6 is a cross-sectional view, taken along line VI-VI in FIG. 5, showing an example of a cross-sectional structure in the memory area of the memory cell array included in the semiconductor memory device according to the embodiment.

FIG. 7 is a cross-sectional view, taken along line VII-VII in FIG. 6, showing an example of a cross-sectional structure of a memory pillar in the semiconductor memory device according to the embodiment.

FIG. 8 is a plan view showing an example of a planar layout in a contact area of the memory cell array included in the semiconductor memory device according to the embodiment.

FIG. 9 is a cross-sectional view, taken along line IX-IX in FIG. 8, showing an example of a cross-sectional structure in the contact area of the memory cell array included in the semiconductor memory device according to the embodiment.

FIG. 10 is a flowchart showing an example of a method of manufacturing the semiconductor memory device according to the embodiment.

FIG. 11 is a cross-sectional view showing an example of a cross-sectional structure of the semiconductor memory device in the course of manufacturing according to the embodiment.

FIG. 12 is a plan view showing an example of a planar layout of the semiconductor memory device in the course of manufacturing according to the embodiment.

FIG. 13 is a cross-sectional view, taken along line XIII-XIII in FIG. 12, showing an example of a cross-sectional structure of the semiconductor memory device in the course of manufacturing according to the embodiment.

FIG. 14 is a plan view showing an example of a planar layout of the semiconductor memory device in the course of manufacturing according to the embodiment.

FIG. 15 is a cross-sectional view, taken along line XV-XV in FIG. 14, showing an example of a cross-sectional structure of the semiconductor memory device in the course of manufacturing according to the embodiment.

FIGS. 16, 17, and 18 are cross-sectional views showing examples of the cross-sectional structure of the semiconductor memory device in the course of manufacturing according to the embodiment.

FIG. 19 is a plan view showing an example of a planar layout of the semiconductor memory device in the course of manufacturing according to the embodiment.

FIG. 20 is a cross-sectional view, taken along line XX-XX in FIG. 19, showing an example of a cross-sectional structure of the semiconductor memory device in the course of manufacturing according to the embodiment.

FIGS. 21, 22, 23, 24, 25, 26, 27, and 28 are cross-sectional views showing examples of the cross-sectional structure of the semiconductor memory device in the course of manufacturing according to the embodiment.

FIG. 29 is a cross-sectional view showing an example of a layout of a hole in a comparative example.

FIG. 30 is a cross-sectional view showing an example of a layout of a hole in the embodiment.

FIG. 31 is a plan view showing an example of a planar layout in a bit line coupling area of the memory cell array included in the semiconductor memory device according to the embodiment.

FIG. 32 is a cross-sectional view showing an example of a cross-sectional structure in a contact area of a memory cell array included in a semiconductor memory device according to a modification of the embodiment.

### DETAILED DESCRIPTION

In general, according to one embodiment, a semiconductor memory device according to an embodiment includes a substrate, a lower interconnect, a source line, word lines, a pillar, a pattern portion, a contact. The lower interconnect is provided above the substrate. The source line is provided in a first layer above the lower interconnect. The word lines are provided above the source line. The word lines are separated from one another in a first direction intersecting a surface of the substrate.

The pillar is provided to extend in the first direction and penetrate the word lines. A bottom portion of the pillar reaches the source line. Intersecting portions of the pillar and the word lines are respectively functioning as memory cells. The pattern portion is provided to be separated and insulated from the source line in the first layer. A contact is extending in the first direction, penetrating the pattern portion, and provided on the lower interconnect. A width of the contact in a second direction parallel to the surface of the substrate differs between a portion above a boundary plane that is included in the first layer and is parallel to the surface of the substrate, and a portion below the boundary plane.

Hereinafter, an embodiment will be described with reference to the drawings. Each embodiment exemplifies a device and a method for embodying a technical idea of the invention. The drawings are schematic or conceptual, and the dimensions and ratios, etc. in the drawings are not always the same as those of the actual products. The technical idea of the present invention is not specified by the shapes, structures, arrangements, etc. of the structural elements.

In the following descriptions, structural elements having substantially the same function and configuration will be assigned the same reference sign. The numbers after the letters that make up the reference signs are used to distinguish between elements referenced by reference signs containing the same letters and having a similar configuration. When there is no need to distinguish elements denoted by reference signs containing the same letters from each other, such elements may be referred to by a reference sign containing the letters only.

### Embodiment

A semiconductor memory device 1 according to an embodiment will be described below.

### [1] Configuration of Semiconductor Memory Device 1

### [1-1] Overall Configuration of Semiconductor Memory Device 1

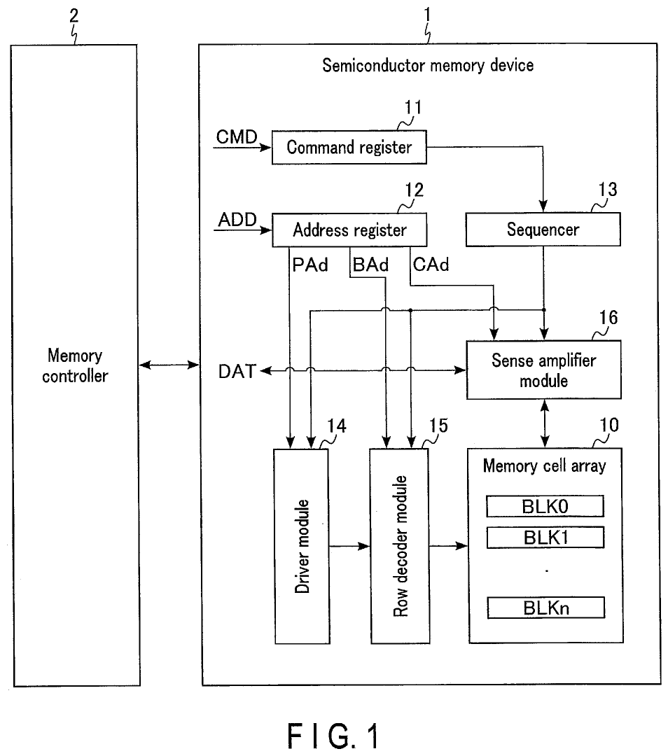

FIG. 1 is a block diagram showing an example of an overall configuration of the semiconductor memory device 1 according to the embodiment. The semiconductor memory device 1 is, for example, a NAND flash memory capable of storing data in a non-volatile manner, and can be controlled by an external memory controller 2. As shown in FIG. 1, the semiconductor memory device 1 includes, for example, a memory cell array 10, a command register 11, an address register 12, a sequencer 13, a driver module 14, a row decoder module 15, and a sense amplifier module 16.

The memory cell array 10 includes a plurality of blocks BLK0 to BLKn (where n is an integer of 1 or more). A block BLK is a set of a plurality of memory cells capable of storing data in a non-volatile manner, and is, for example, used as a unit of erasing data. The memory cell array 10 is provided with a plurality of bit lines and a plurality of word lines. Each memory cell is, for example, associated with one bit line and one word line. A detailed configuration of the memory cell array 10 will be described later.

The command register 11 holds a command CMD received by the semiconductor memory device 1 from the memory controller 2. The command CMD includes, for example, an instruction to cause the sequencer 13 to execute a read operation, a write operation, an erase operation, etc.

The address register 12 holds address information ADD received by the semiconductor memory device 1 from the memory controller 2. The address information ADD contains, for example, a block address BAd, a page address PAd, and a column address CAd. For example, the block address BAd, page address PAd, and column address CAd are used to select a block BLK, a word line, and a bit line, respectively.

The sequencer 13 takes total control over the operations of the semiconductor memory device 1. For example, the sequencer 13 controls the driver module 14, row decoder module 15, and sense amplifier module 16, etc., based on a command CMD held in the command register 11, to execute a read operation, a write operation, an erase operation, etc.

The driver module 14 generates voltages used in a read operation, a write operation, an erase operation, etc. Then, the driver module 14 applies a generated voltage to a signal line corresponding to a selected word line based on, for example, the page address PAd held in the address register 12.

Based on the block address BAd held in the address register 12, the row decoder module 15 selects one corresponding block BLK in the memory cell array 10. Then, for example, the row decoder module 15 transfers the voltage that has been applied to the signal line corresponding to the selected word line to this selected word line in the selected block BLK.

In a write operation, the sense amplifier module 16 applies a desired voltage to each bit line in accordance with write data DAT received from the memory controller 2. In a read operation, the sense amplifier module 16 judges data stored in a memory cell based on the voltage of the corresponding bit line, and transfers the judgment result to the memory controller 2 as read data DAT.

The above-described semiconductor memory device 1 and memory controller 2 may be combined into a single semiconductor device. Examples of such semiconductor devices include a memory card such as an SD™ card and a solid state drive (SSD).

### [1-2] Circuit Configuration of Semiconductor Memory Device 1

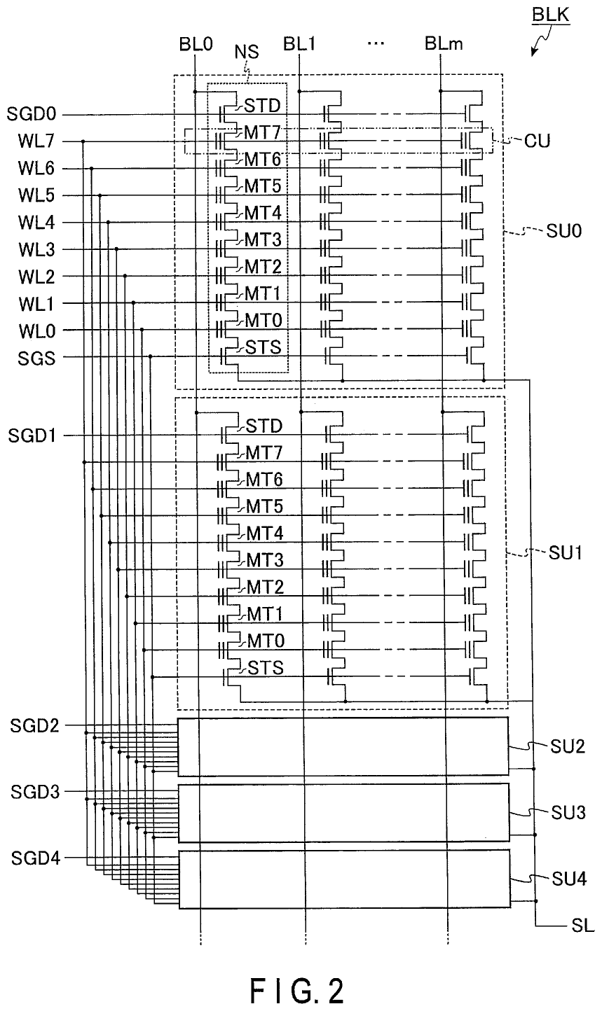

FIG. 2 is a circuit diagram showing an example of a circuit configuration of the memory cell array 10 included in the semiconductor memory device 1 according to the embodiment. FIG. 2 shows one block BLK of a plurality of blocks BLK included in the memory cell array 10. As shown in FIG. 2, the block BLK contains, for example, five string units SU0 to SU4.

Each string unit SU includes a plurality of NAND strings NS respectively associated with bit lines BL0 to BLm (m is an integer of 1 or more). Each NAND string NS includes, for example, memory cell transistors MT0 to MT7 and select transistors STD and STS. Each memory cell transistor MT includes a control gate and a charge storage layer, and stores data in a non-volatile manner. The select transistors STD and STS are each used to select a string unit SU in various operations.

In each NAND string NS, the memory cell transistors MT0 to MT7 are coupled in series. The drain of the select transistor STD is coupled to an associated bit line BL. The source of the select transistor STD is coupled to one end of a set of memory cell transistors MT0 to MT7 coupled in series. The drain of the select transistor STS is coupled to the other end of the set of memory cell transistors MT0 to MT7 coupled in series. The source of the select transistor STS is coupled to a source line SL.

Within a block BLK, the control gates of sets of memory cell transistors MT0 to MT7 are coupled to the word lines WL0 to WL7, respectively. The gates of a plurality of select transistors STD in the string unit SU0 are coupled to a select gate line SGD0. The gates of a plurality of select transistors STD in the string unit SU1 are coupled to a select gate line SGD1. The gates of a plurality of select transistors STD in the string unit SU2 are coupled to a select gate line SGD2. The gates of a plurality of select transistors STD in the string unit SU3 are coupled to a select gate line SGD3. The gates of a plurality of select transistors STD in the string unit SU4 are coupled to a select gate line SGD4. The gates of a plurality of select transistors STS are coupled to a select gate line SGS.

Different column addresses are respectively assigned to the bit lines BL0 to BLm. Each bit line BL is shared by the NAND strings NS to which the same column address is assigned among a plurality of blocks BLK. The word lines WL0 to WL7 as a group are provided for each block BLK. The source line SL is, for example, shared by a plurality of blocks BLK.

A set of a plurality of memory cell transistors MT coupled to a common word line WL within one string unit SU may be referred to as, for example, a “cell unit CU”. For example, the storage capacity of a cell unit CU including memory cell transistors MT each storing 1-bit data is defined as “1-page data”. The cell unit CU may have a storage capacity of 2-page data or more in accordance with the number of bits of data stored in the memory cell transistors MT.

The circuit configuration of the memory cell array 10 included in the semiconductor memory device 1 according to the embodiment is not limited to the above. For example, the number of string units SU included in each block BLK and the numbers of memory cell transistors MT and select transistors STD and STS included in each NAND string NS may be any number.

### [1-3] Structure of Semiconductor Memory Device 1

An example of a structure of the memory cell array 10 included in the semiconductor memory device 1 according to the embodiment will be described below. In the drawings to be referred to hereinafter, a direction in which the word lines WL extend is referred to as an “X direction”, a direction in which the bit lines BL extend is referred to as a “Y direction”, and a direction vertical to the surface of a semiconductor substrate 20 used for formation of the semiconductor memory device 1 is referred to as a “Z direction”. In the plan views, hatching is added as appropriate to facilitate visualization of the drawings. The hatching added to the plan views, however, may not necessarily relate to the materials or properties of the hatched structural elements. In the plan views and cross-sectional views, some structures are omitted as appropriate to facilitate visualization of the drawings.

### [1-3-1] Planar Layout of Semiconductor Memory Device 1

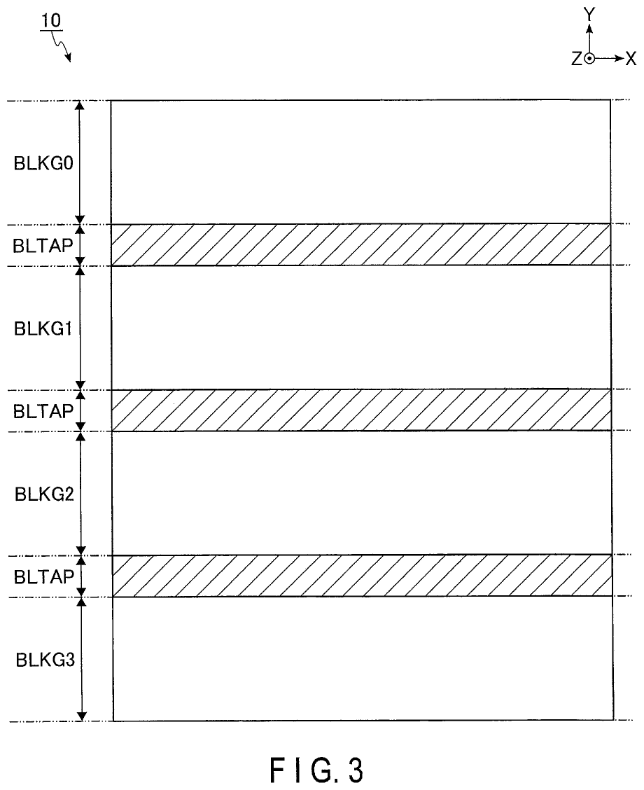

FIG. 3 is a plan view showing an example of a planar layout of the memory cell array 10 included in the semiconductor memory device 1 according to the embodiment. As shown in FIG. 3, the memory cell array 10 includes, for example, block groups BLKG0 to BLKG3.

Each block group BLKG includes a plurality of blocks BLK. Each block group BLKG is provided to extend in the X direction. The block groups BLKG0 to BLKG3 are arranged in the Y direction. A bit line coupling area BLTAP is provided between any block groups BLKG adjacent in the Y direction. The bit line coupling area BLTAP is an area in which a contact for electrically coupling a bit line BL and the sense amplifier module 16 is formed. The number of block groups BLKG may be any number. The bit line coupling area BLTAP may be arranged in an area not sandwiched between adjacent block groups BLKG.

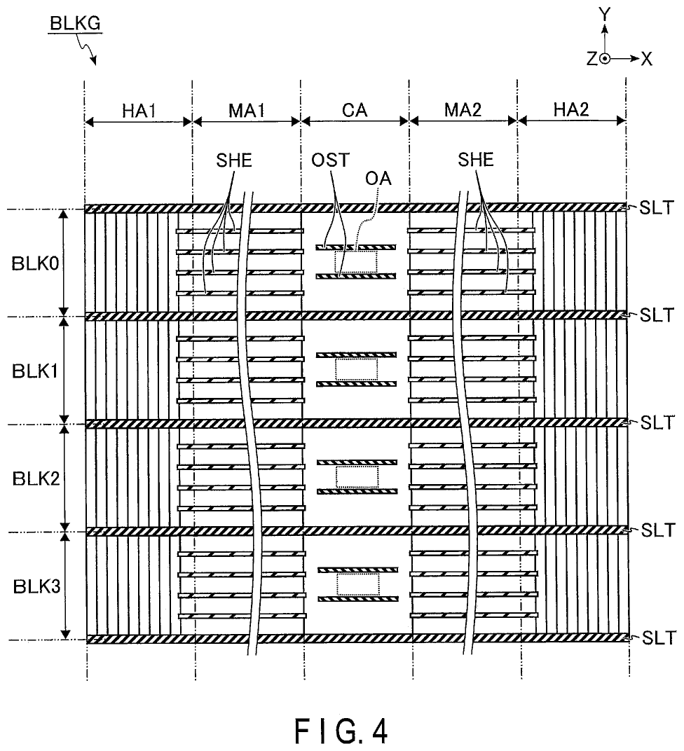

FIG. 4 is a plan view showing an example of a planar layout of the block group BLKG in the memory cell array 10 included in the semiconductor memory device 1 according to the embodiment. As shown in FIG. 4, the block group BLKG includes, for example, the blocks BLK0 to BLK3. The area of the block group BLKG is divided into, for example, memory areas MA1 and MA2, hookup areas HA1 and HA2, and a contact area CA in the X direction. In the area of the block group BLKG, the memory cell array 10 includes, for example, a plurality of slits SLT, a plurality of slits SHE, and a plurality of slits OST.

Each block BLK is provided to extend in the X direction. The blocks BLK0 to BLK3 are arranged in the Y direction. The number of blocks BLK included in the block group BLK1 may be any number. The block group BLKG may include a dummy block not used for storing data.

The memory areas MA1 and MA2 are arranged between the hookup areas HA1 and HA2. The contact area CA is arranged between the memory areas MA1 and MA2. Each of the memory areas MA1 and MA2 includes a plurality of NAND strings NS. Each of the hookup areas HA1 and HA2 includes, for example, a staircase structure of stacked interconnects including the word lines WL and the select gate lines SGD and SGS. A plurality of contacts for electrically coupling the stacked interconnects coupled to the NAND strings NS and the row decoder module 15 are coupled to that staircase structure. The contact area CA includes a contact that penetrates the stacked interconnects. Hereinafter, a portion where the stacked interconnects including the word lines WL and the select gate lines SGD and SGS are provided in the memory cell array 10 is also referred to as a “stacked interconnect portion”.

Each slit SLT includes a portion that extends in the X direction. The slits SLT are arranged in the Y direction. Each of areas sectioned by the slits SLT in the Y direction corresponds to one block BLK. Each slit SLT crosses the memory areas MA1 and MA2, the hookup areas HA1 and HA2, and the contact area CA in the X direction. The slit SLT has, for example, a structure in which an insulator and a conductor are embedded. Each slit SLT divides interconnects (e.g., the word lines WL0 to WL7 and select gate lines SGD and SGS) adjacent via that slit SLT.

The slits SHE are arranged in each of the memory areas MA1 and MA2. The slits SHE corresponding to the memory area MA1 are each provided across the memory area MA1, and are arranged in the Y direction. The slits SHE corresponding to the memory area MA2 are each provided across the memory area MA2, and are arranged in the Y direction. Each of the areas sectioned by the slits SLT and SHE in the Y direction corresponds to a single string unit SU. Each slit SHE has a structure in which an insulator is embedded. In the present example, four slits SHE are arranged between any slits SLT adjacent in the Y direction. Each slit SHE divides interconnects (at least the select gate line SGD) that are adjacent to each other via that slit SHE.

Slits OST are arranged in the contact area CA. Each slit OST includes a portion that extends in the X direction. In the present example, two slits OST are arranged between any adjacent slits SLT. Two slits OST arranged between adjacent slits SLT are arranged away from each other, and are arranged in the Y direction. Each slit OST has a structure in which an insulator is embedded. A penetration area OA is provided between two slits OST provided between adjacent slits SLT. The penetration area OA is an area in which at least one penetration contact is provided. The penetration contact will be described in detail later.

In the block group BLKG, the layout shown in FIG. is repeatedly arranged in the Y direction. The planar layout of the block group BLKG included in the semiconductor memory device 1 according to the embodiment is not limited to the above-described layout. The number of slits SHE arranged between adjacent slits SLT may be freely designed. The number of string units SU formed between adjacent slits SLT may be changed based on the number of slits SHE arranged between the adjacent slits SLT. The memory cell array 10 includes a plurality of contact areas CA. The contact area CA may be inserted into a hookup area HA. Two or more penetration areas OA may be provided. The hookup area HA may be arranged between two memory areas MA.

### [1-3-2] Structure in Memory Area MA (Planar Layout of Memory Area MA)

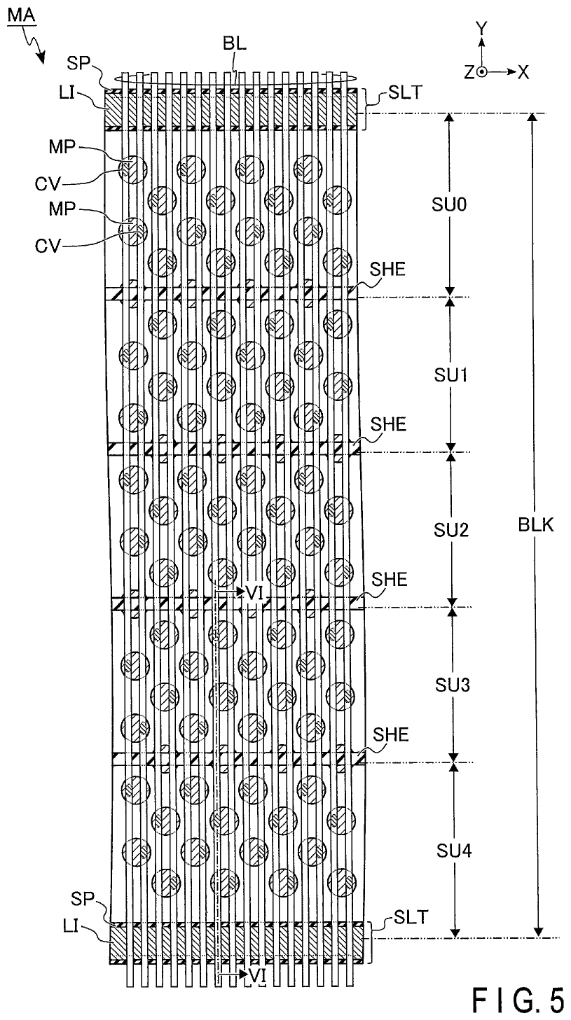

FIG. 5 is a plan view showing an example of a planar layout in the memory area MA of the memory cell array 10 included in the semiconductor memory device 1 according to the embodiment. FIG. 5 shows an area including one block BLK (i.e., string units SU0 to SU4). As shown in FIG. 5, the memory cell array 10 further includes, for example, a plurality of memory pillars MP, a plurality of contacts CV, and a plurality of bit lines BL, in the memory area MA. In addition, each slit SLT includes a contact LI and a spacer SP.

Each memory pillar MP functions as, for example, one NAND string NS. The memory pillars MP are in, for example, a 24-row staggered arrangement in an area between two adjacent slits SLT. For example, a single slit SHE overlaps each set of the memory pillars MP in the fifth row, the memory pillars MP in the tenth row, the memory pillars MP in the fifteenth row, and the memory pillars MP in the twentieth row, counting from the top of the drawing.

The bit lines EL, each of which includes a portion that extends in the Y direction, are arranged in the X direction. Each bit line BL is arranged so as to overlap at least one memory pillar MP in each string unit SU. In the present example, one memory pillar MP is overlapped with two bit lines BL. One of a plurality of bit lines BL that overlap a memory pillar MP and that memory pillar MP are electrically coupled via a contact CV.

For example, a contact CV is omitted between a memory pillar MP in contact with a slit SHE and a bit line BL. In other words, a contact CV is omitted between a memory pillar MP in contact with two different select gate lines SGD and a bit line BL. The numbers and arrangement of memory pillars MP, slits SHE, etc. provided between any adjacent slits SLT are not limited to the configuration described using FIG. 5, and may be modified as appropriate. The number of bit lines BL that overlap each memory pillar MP can be freely designed.

The contact LI is a conductor including a portion that extends in the X direction, and is coupled to the source line SL. The spacer SP is an insulator provided on a side surface of the contact LI. The contact LI is sandwiched by the spacers SP. The contact LI and a conductor (e.g., the word lines WL0 to WL7, and the select gate lines SGD and SGS) adjacent to that contact LI in the Y direction are separated and insulated by the spacer SP. The spacer SP is, for example, an oxide film. The contact LI may also be referred to as a “source line contact”.

### Cross-Sectional Structure of Memory Area MA

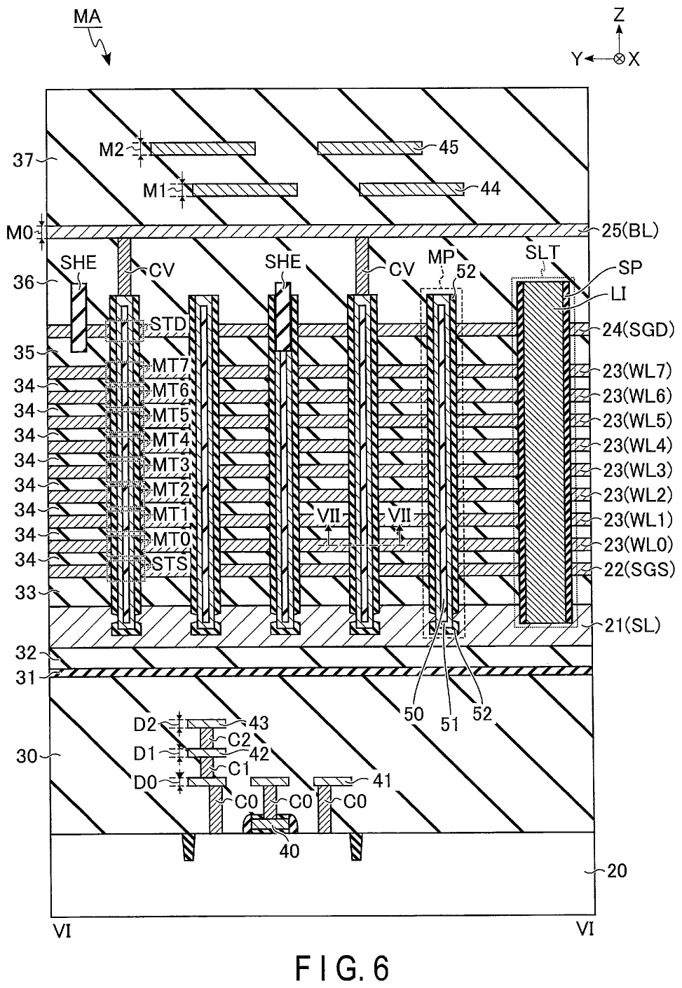

FIG. 6 is a cross-sectional view, taken along line VI-VI in FIG. 5, showing an example of a cross-sectional structure in the memory area MA of the memory cell array 10 included in the semiconductor memory device 1 according to the embodiment. As shown in FIG. 6, the semiconductor memory device 1 further includes, for example, the semiconductor substrate 20, conductive layers 21 to 25, and insulating layers 30 to 37 in the memory area MA.

The semiconductor substrate 20 is, for example, a P-type semiconductor substrate. The insulating layer 30 is provided on the semiconductor substrate 20. The insulating layer 30 covers circuits coupled to the row decoder module 15, the sense amplifier module 16, etc. formed on the semiconductor substrate 20, and may be formed of a plurality of layers. For example, the circuits covered by the insulating layer 30 include conductive layers 40 to 43 and contacts C0 to C2. The conductive layer 40 is provided on the semiconductor substrate 20 with a gate insulating film interposed therebetween. The conductive layer 40 functions as a gate electrode of a transistor provided below the stacked interconnect portion. The plurality of contacts C0 are provided on the conductive layer 40 and on the semiconductor substrate 20. The contacts C0 provided on the semiconductor substrate 20 are coupled to an impurity diffusion region (not shown) provided in the semiconductor substrate 20. The conductive layer 41 is provided on the contacts C0. The contact C1 is provided on the conductive layer 41. The conductive layer 42 is provided on the contact C1. The contact C2 is provided on the conductive layer 42. The conductive layer 43 is provided on the contact C2.

The insulating layer 31 is provided on the insulating layer 30. The insulating layer 31 contains, for example, silicon nitride. The insulating layer 31 prevents hydrogen, which is generated in, for example, a thermal process for forming a stacked interconnect portion, from entering a transistor provided on the semiconductor substrate 20. The insulating layer 31 may be referred to as a barrier film. The insulating layer 32 is provided on the insulating layer 31. The conductive layer 21 is provided on the insulating layer 32. The conductive layer 21 is, for example, formed in a plate shape expanding along an XY plane, and is used as the source line SL. The conductive layer 21 contains, for example, phosphorous-doped silicon.

The insulating layer 33 is provided on the conductive layer 21. The conductive layer 22 is provided on the insulating layer 33. The conductive layer 22 is, for example, formed in a plate shape expanding along the XY plane, and is used as a select gate line SGS. The conductive layer 22 contains, for example, tungsten. The insulating layers 34 and the conductive layers 23 are alternately stacked on the conductive layer 22. The conductive layer 23 is, for example, formed in a plate shape expanding along the XY plane. The stacked conductive layers 23 are used as word lines WL0 to WL7 in the named order from the semiconductor substrate 20 side. The conductive layers 23 each contain, for example, tungsten.

The insulating layer 35 is provided on the uppermost conductive layer 23. The conductive layer 24 is provided on the insulating layer 35. The conductive layer 24 is, for example, formed in a plate shape expanding along the XY plane, and is used as a select gate line SGD. The conductive layer 24 contains, for example, tungsten.

The insulating layer 36 is provided on the conductive layer 24. The conductive layer 25 is provided on the insulating layer 36. The conductive layer 25 is, for example, formed in a linear shape extending in the Y direction, and is used as a bit line BL. Namely, the plurality of conductive layers 25 are arranged in the X direction in an unillustrated area. The conductive layer 25 contains, for example, copper.

The insulating layer 37 is provided on the conductive layer 25. The insulating layer 37 covers circuits for coupling the memory cell array 10 to the row decoder module 15 and the sense amplifier module 16, and may be formed of a plurality of layers. For example, the circuits covered by the insulating layer 37 include conductive layers 44 and 45. The conductive layer 44 is provided in a layer of a higher level than the conductive layer 25, and is spaced apart from the conductive layer 25. The conductive layer 45 is provided in a layer of a higher level than the conductive layer 44, and is spaced apart from the conductive layer 44.

Each of the memory pillars MP is provided to extend in the Z direction, penetrating the insulating layers 33 to 35 and the conductive layers 22 to 24. A bottom portion of the memory pillar MP reaches the conductive layer 21. A portion where the memory pillar MP and the conductive layer 22 intersect functions as a select transistor STS. A portion where the memory pillar MP and one conductive layer 23 intersect functions as one memory cell transistor MT. A portion where the memory pillar MP and the conductive layer 24 intersect functions as a select transistor STD.

In addition, each of the memory pillars MP includes, for example, a core member 50, a semiconductor layer 51, and a stacked film 52. The core member 50 is provided to extend in the Z direction. For example, an upper end of the core member 50 is included in a layer above the conductive layer 24, and a lower end of the core member 50 is included in the interconnect layer in which the conductive layer 21 is provided. The semiconductor layer 51 covers the periphery of the core member 50. A part of the semiconductor layer 51 is in contact with the conductive layer 21 via a side surface of the memory pillar MP. The stacked film 52 covers the side and bottom surfaces of the semiconductor layer 51 except for the portion where the semiconductor layer 51 and the conductive layer 21 are in contact with each other. The core member 50 contains an insulator, such as silicon oxide. The semiconductor layer 51 contains, for example, silicon.

A columnar contact CV is provided on the semiconductor layer 51 in the memory pillar MP. In the illustrated area, two contacts CV respectively corresponding to two of the five memory pillars MP are shown. In the memory area MA, to a memory pillar MP which does not overlap the slit SHE and to which a contact CV is not coupled, a contact CV is coupled in an unillustrated area.

A single conductive layer 25, i.e., a single bit line BL, is in contact with the upper surface of the contact CV. In each of the spaces sectioned by the slits SLT and SHE, one contact CV is coupled to the single conductive layer 25. That is, a memory pillar MP provided between any adjacent slits SLT and SHE and a memory pillar MP provided between any two adjacent slits SHE are electrically coupled to each conductive layer 25.

The slit SLT includes, for example, a portion provided along the XZ plane, and divides the conductive layers 22 to 24 and the insulating layers 33 to 35. In the slit SLT, the contact LI is provided along the slit SLT. A part of the upper end of the contact LI is in contact with the insulating layer 36. The lower end of the contact LI is in contact with the conductive layer 21. The contact LI is, for example, used as a part of the source line SL. The spacer SP is provided at least between the contact LI and the conductive layers 22 to 24. The contact LI is separated and insulated from the conductive layers 22 to 24 by the spacer SP.

The slit SHE includes, for example, a portion provided along the XZ plane and divides at least the conductive layer 24. The upper end of the slit SHE is in contact with the insulating layer 36. The lower end of the slit SHE is in contact with the insulating layer 35. The slit SHE includes an insulator such as silicon oxide. The upper end of the slit SHE and the upper end of the slit SLT may or may not be aligned. Furthermore, the upper end of the slit SHE and the upper end of the memory pillar MP may or may not be aligned.

Hereinafter, interconnect layers in which the conductive layers 41, 42 and 43 are provided will be referred to as “D0”, “D1” and “D2”, respectively. Interconnect layers in which the conductive layers 25, 44 and 45 are provided will be referred to as “M0” “M1” and “M2”, respectively.

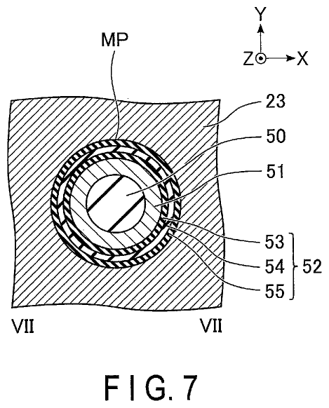

FIG. 7 is a cross-sectional view taken along line VII-VII in FIG. 6, showing an example of a cross-sectional structure of the memory pillar MP in the semiconductor memory device 1 according to the embodiment. FIG. 7 shows a cross-sectional structure of the memory pillar MP in a layer that is parallel to the surface of the semiconductor substrate 20 and includes the conductive layer 23. As shown in FIG. 7, the stacked film 52 includes, for example, a tunnel insulating film 53, an insulating film 54, and a block insulating film 55.

In the cross section including the conductive layer 23, the core member 50 is provided in the middle of the memory pillar MP. The semiconductor layer 51 surrounds a side surface of the core member 50. The tunnel insulating film 53 surrounds a side surface of the semiconductor layer 51. The insulating film 54 surrounds a side surface of the tunnel insulating film 53. The block insulating film 55 surrounds a side surface of the insulating film 54. The conductive layer 23 surrounds a side surface of the block insulating film 55. Each of the tunnel insulating film 53 and the block insulating film 55 contains, for example, silicon oxide. The insulating film 54 contains, for example, silicon nitride.

In each of the memory pillars MP described above, the semiconductor layer 51 is used as a channel (current path) of the memory cell transistors MT0 to MT7 and the select transistors STD and STS. The insulating film 54 is used as a charge storage layer of the memory cell transistors MT. The semiconductor memory device 1 can pass an electric current through the memory pillar MP between the bit line BL and the contact LI by turning on the memory cell transistors MT0 to MT7 and the select transistors STD and STS.

### [1-3-3] Structure in Contact Area CA

### Planar Layout of Contact Area CA

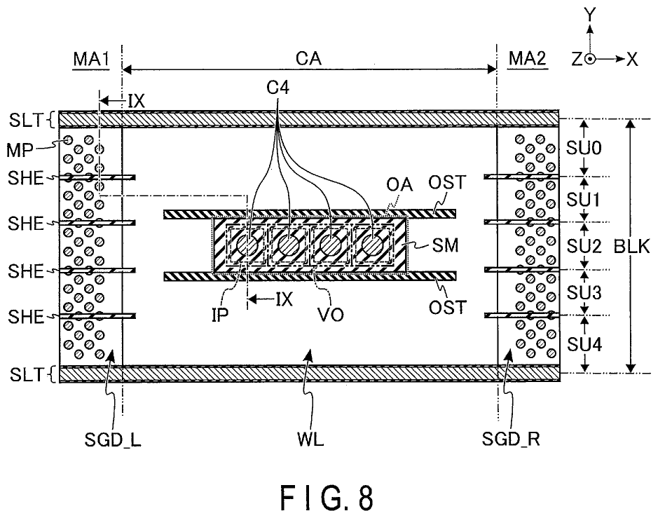

FIG. 8 is a plan view showing an example of a planar layout in the contact area CA of the memory cell array 10 included in the semiconductor memory device 1 according to the embodiment. FIG. 8 shows a region in which one block BLK and the contact area CA overlap, and a part of the memory areas MA1 and MA2 in the vicinity of the contact area CA. As shown in FIG. 8, a select gate line SGD (“SGD_L” in FIG. 8) provided in the memory area MA1 and a select gate line SGD (“SGD_R” in FIG. 8) provided in the memory area MA2 are split via the contact area CA. The select gate lines SGD_L and SGD_R associated with the same string unit SU are electrically coupled via unillustrated contact and interconnect. On the other hand, word lines WL provided at the same height in the memory areas MA1 and MA2 are continuously provided via the contact area CA, and are electrically coupled.

In the penetration area OA, the memory cell array 10 further includes a sacrificial member SM, a plurality of island portions IP, and a plurality of contacts C4. The sacrificial member SM is a member that is used for a replacement process of the stacked interconnect portion. In the replacement process, the sacrificial member SM within the penetration area OA corresponds to a portion of an insulator that remains without having been replaced by a conductor, and is provided at the same height as that of the conductive layer 23. The sacrificial member SM is in contact with each of the slits OST adjacent in the Y direction. Thus, the slits OST are in contact with a plurality of sacrificial members SM and a plurality of word lines WL. In the penetration area OA, the sacrificial member SM separates, in the X direction, the word lines WL which are in contact with the sacrificial member SM on the memory area MA1 side, and the word lines WL which are in contact with the sacrificial member SM on the memory area MA2 side. The sacrificial member SM contains, for example, silicon nitride.

The island portions IP are arranged in the X direction. Each island portion IP may be referred to as an island-shaped “pattern portion”. The island portion IP has a stacked structure that is used for formation of the source line SL, and is provided away from the source line SL. An insulator including a void VO is provided between the island portion IP and the source line SL. Any adjacent island portions IP are separated and insulated by the insulator including the void VO. A stacked structure of the island portion IP will be described in detail later. Each contact C4 is provided to penetrate the sacrificial members SM, and corresponds to a “penetration contact”. The contacts C4 are arranged so as to respectively overlap the island portions IP. Each contact C4 electrically couples an upper interconnect of the stacked interconnect portion and a lower interconnect of the stacked interconnect portion, and is insulated from the word lines WL, etc.

### Cross-Sectional Structure of Contact Area CA

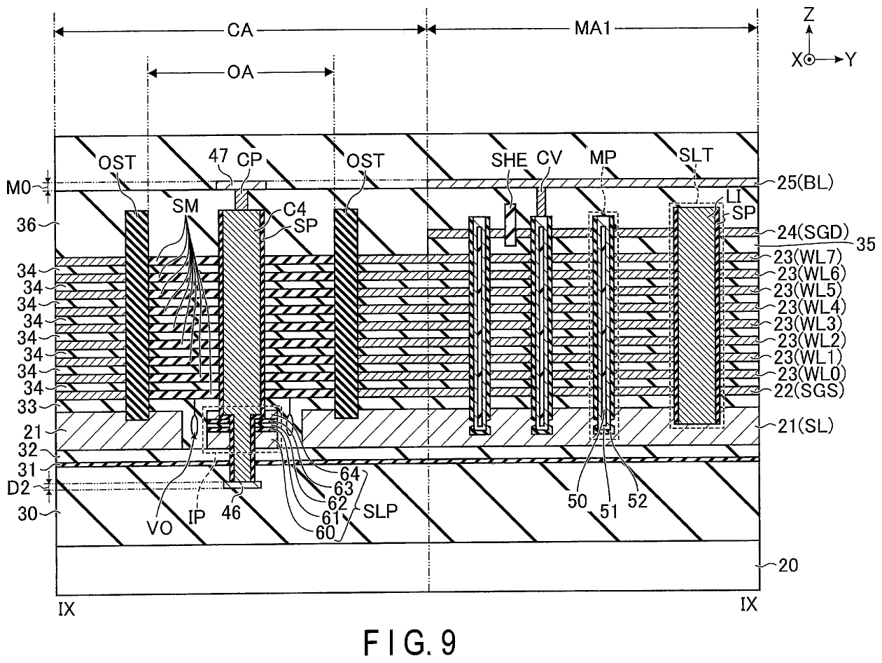

FIG. 9 is a cross-sectional view taken along line IX-IX in FIG. 8, showing an example of a cross-sectional structure in the contact area CA of the memory cell array 10 included in the semiconductor memory device 1 according to the embodiment. FIG. 9 shows a portion including the contact C4 within the contact area CA, and a part of the memory area MA1. As shown in FIG. 9, the memory cell array 10 includes a conductive layer 46, a contact CP, and a conductive layer 47 in the contact area CA. The island portion IP includes, for example, a conductive layer 60, an insulating layer 61, a sacrificial member 62, an insulating layer 63, and a conductive layer 64.

The conductive layer 46 is an interconnect provided in an interconnect layer D2, and is electrically coupled to a circuit provided below the stacked interconnect portion. The contact C4 is provided on the conductive layer 46. The contact CP is provided on the contact C4. The conductive layer 47 is provided on the contact CP. The conductive layer 47 is an interconnect provided in the interconnect layer MO, and is electrically coupled to a circuit provided above the stacked interconnect portion. Thereby, the circuits above and below the stacked interconnect portion, i.e., the conductive layers 46 and 47, are electrically coupled via the contacts C4 and CP. Note that it suffices that the conductive layers 46 and 47 are at least electrically coupled via the contact C4. The conductive layer 46 may be referred to as a “lower interconnect”. The conductive layer 47 may be referred to as an “upper interconnect”.

A set of the conductive layer 60, the insulating layer 61, the sacrificial member 62, the insulating layer 63, and the conductive layer 64 that form a stacked structure in the island portion IP is located at the same height as that of the conductive layer 21, i.e., provided in the same layer. Specifically, the conductive layer 60, the insulating layer 61, the sacrificial member 62, the insulating layer 63, and the conductive layer 64 are stacked in this order on the insulating layer 32. The height of the lower surface of the conductive layer 60 and that of the lower surface of the conductive layer 21 are aligned, i.e., are approximately the same. The height of the upper surface of the conductive layer 64 and that of the upper surface of the conductive layer 21 are aligned, i.e., are approximately the same.

The insulating layer 33 is provided on the conductive layer 64. The insulating layer 33 covers the side surfaces and upper surface of the island portion IP. In other words, the insulating layer 33 includes a first portion provided between the island portion IP and the source line SL, and a second portion provided on the source line SL. Thereby, the insulating layer 33 separates and insulates the island portion IP and the conductive layer 21. The first portion of the insulating layer 33 includes a void VO. The void VO can surround the island portion IP in a plan view. A seam of the insulating layer 33 can be formed on the void VO. Each of the conductive layers 60 and 64 contains, for example, phosphorous-doped silicon. Each of the insulating layers 61 and 63 is, for example, an oxide film. The sacrificial member 62 contains, for example, silicon nitride.

The slit OST includes a portion that extends in the Z direction. The upper end of the slit OST reaches the insulating layer 36, for example. The lower end of the slit OST reaches the conductive layer 21, for example. In an illustrated cross-sectional portion, in a portion that is at the same layer as the conductive layer 22 and that is interposed by the two slits OST, a sacrificial member SM is provided. Similarly, in the illustrated cross-sectional portion, i.e., within the penetration area OA, in portions that are at the same layers as the conductive layers 23 and that are interposed by the two slits OST, sacrificial members SM are provided. In other words, in the penetration area OA, the sacrificial members SM and the insulating layers 34 are alternately stacked. In the contact area CA, for example, the insulating layer 36 is provided between each of the uppermost sacrificial member SM and the uppermost conductive layer 23, and the interconnect layer M0.

The contact C4 is provided to extend in the Z direction. The contact C4 penetrates the insulating layers 31 and 32, island portion IP, insulating layer 33, and the alternately stacked insulating layers 34 and sacrificial members SM. Then, a width of the contact C4 as viewed in a direction parallel to the surface of the substrate 20 differs between a portion above a boundary plane that is included in the layer in which the stacked structure of the island portion IP is provided and is parallel to the surface of the substrate 20, and a portion below the boundary plane. Then, the width of the contact C4 as viewed in the direction parallel to the surface of the substrate 20 discontinuously changes at the boundary plane, and is smaller at a portion below the boundary plane than at a portion above the boundary plane. In other words, with a height between the upper surface of the conductive layer 64 and the lower surface of the conductive layer 60 as a boundary, the contact C4 includes a narrowed portion on the lower side of the boundary plane. The spacer SP provided on the side surface of the contact C4 may be terminated at an intermediate level corresponding the boundary plane. The contact C4 and each of the stacked sacrificial members SM and conductive layers 60 and 64 are separated and insulated by the spacer SP. In a case where the spacer SP is terminated at the intermediate level of the contact C4, the contact C4 and the conductive layer 64 may be electrically coupled.

Hereinafter, the set of the conductive layer 60, insulating layer 61, sacrificial member 62, insulating layer 63, and conductive layer 64 will be referred to as a “source line portion SLP”. Note that a structure of the source line portion SLP may remain in a portion in which the conductive layer 21 is provided within the contact area CA shown in FIG. 9. The insulating layer 61 and the sacrificial member 62 are members that are used for a replacement process of the source line SL, and thus may be appropriately omitted within the contact area CA. The height of the lower surface of the source line portion SLP and that of the lower surface of the conductive layer 21 may be aligned whenever the insulating layer 61 and the sacrificial member 62 are omitted from the source line portion within the contact area CA. The height of the upper surface of the source line portion SLP from which the insulating layer 61 and the sacrificial member 62 are omitted can be lower than that of the upper surface of the conductive layer 21.

### [2] Manufacturing Method of Semiconductor Memory Device 1

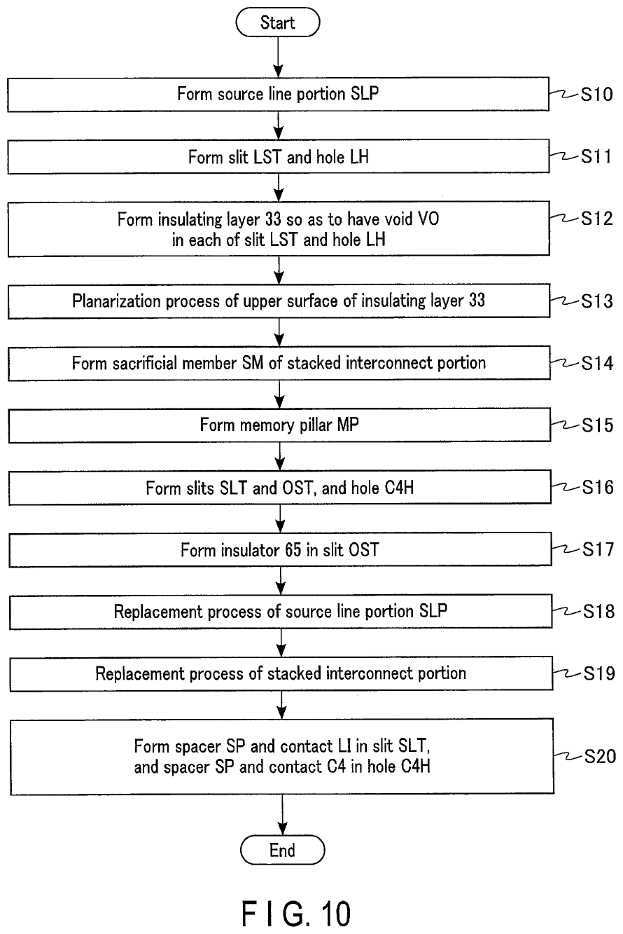

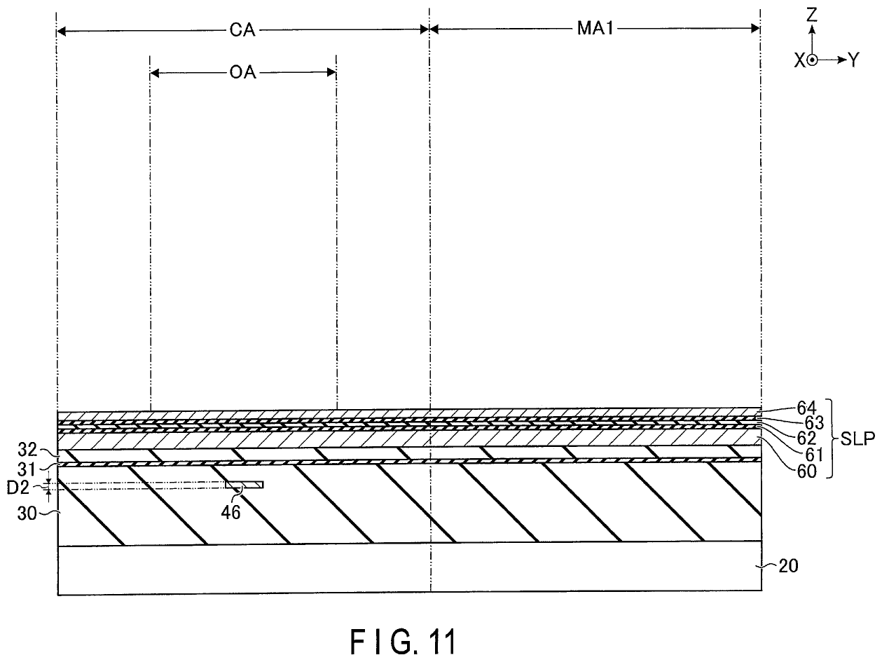

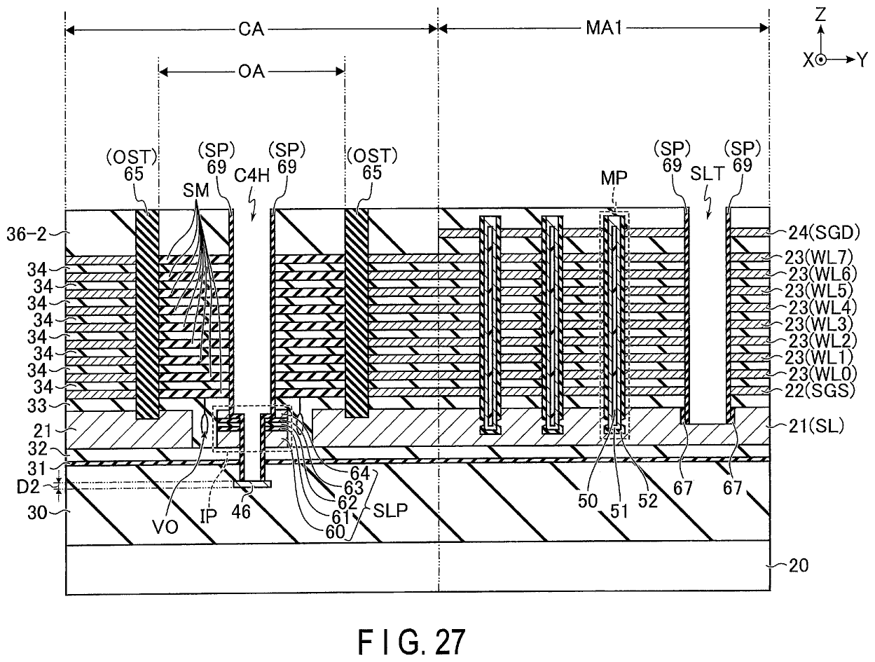

FIG. 10 is a flowchart showing an example of a manufacturing method of the semiconductor memory device 1 according to the embodiment. FIGS. 11 to 28 each show an example of a planar layout or a cross-sectional structure of the semiconductor memory device 1 in the course of manufacturing according to the embodiment. The plan views and cross-sectional views that are used for explanation of the manufacturing method each show the same area as those of FIGS. 8 and 9. In the following, an example of manufacturing processes from formation of the source line portion SLP to formation of the contacts C4 and LI in the semiconductor memory device 1 according to the embodiment will be described with reference to FIG. 10 as appropriate.

First, as shown in FIG. 11, the source line portion SLP is formed (step S10). That is, the structure between the semiconductor substrate 20 and the insulating layer 30 described using FIG. 6 is formed on the semiconductor substrate 20. FIG. 11 extracts and shows one conductive layer 46 among the circuits covered by the insulating layer 30. The insulating layers 31 and 32 are formed in this order on the insulating layer 30. Then, the source line portion SLP (the conductive layer 60, insulating layer 61, sacrificial member 62, insulating layer 63, and conductive layer 64) is formed on the insulating layer 32.

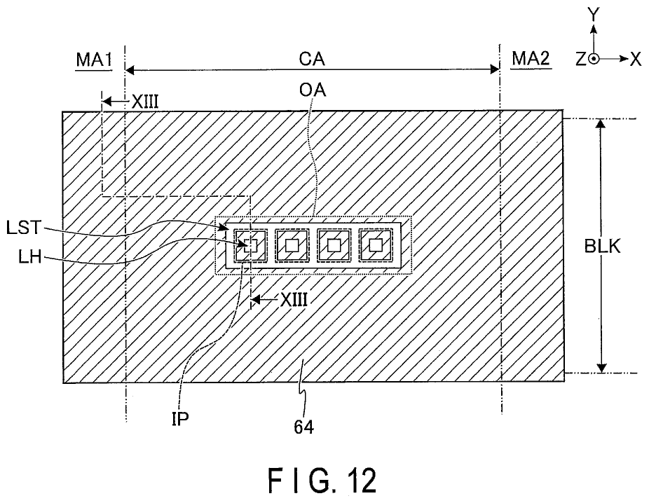

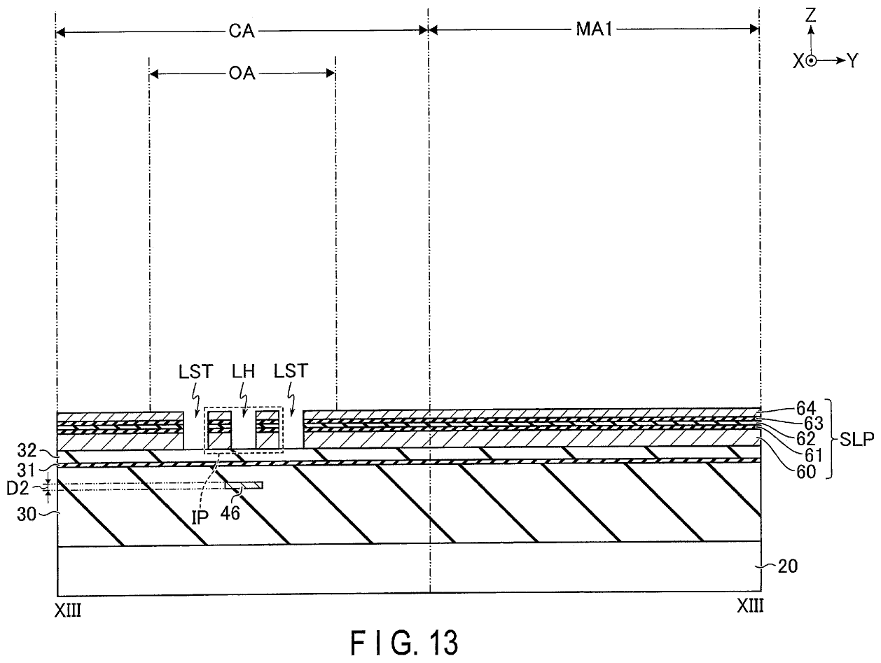

Next, a slit LST and holes LH are formed (step S11). Specifically, as shown in FIG. 12, the conductive layer 64, etc. is processed by a combination of photolithography and anisotropic etching, for example, so that the slit LST and the plurality of holes LH are formed. The slit LST is provided in a region within the penetration area OA and excluding portions corresponding to the island portions IP. The holes LH are provided to respectively overlap the portions corresponding to the island portions IP. Each island portion IP is processed into a ring shape in a plan view by the slit LST and one hole LH. FIG. 13 shows a cross section taken along line XIII-XIII in FIG. 12. As shown in FIG. 13, the slit LST divides a part of each of the conductive layer 64, insulating layer 63, sacrificial member 62, insulating layer 61, and conductive layer 60. Each hole LH penetrates a part of each of the conductive layer 64, insulating layer 63, sacrificial member 62, insulating layer 61, and conductive layer 60. At the bottom of each of the slit LST and hole LH, the insulating layer 32 is exposed. Note that the anisotropic etching used in step S11 is, for example, reactive ion etching (RIE).

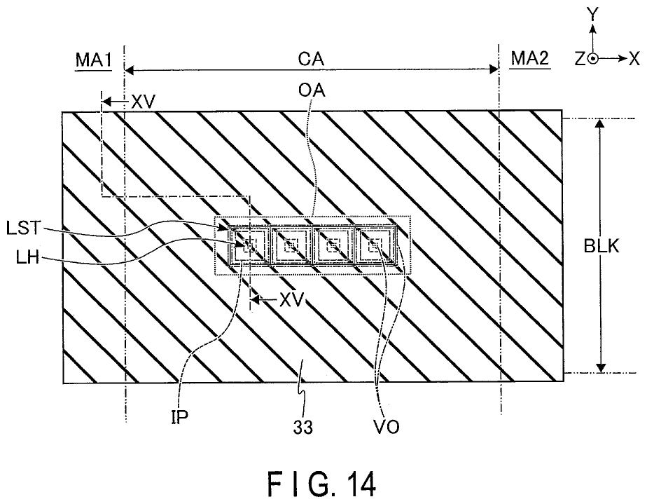

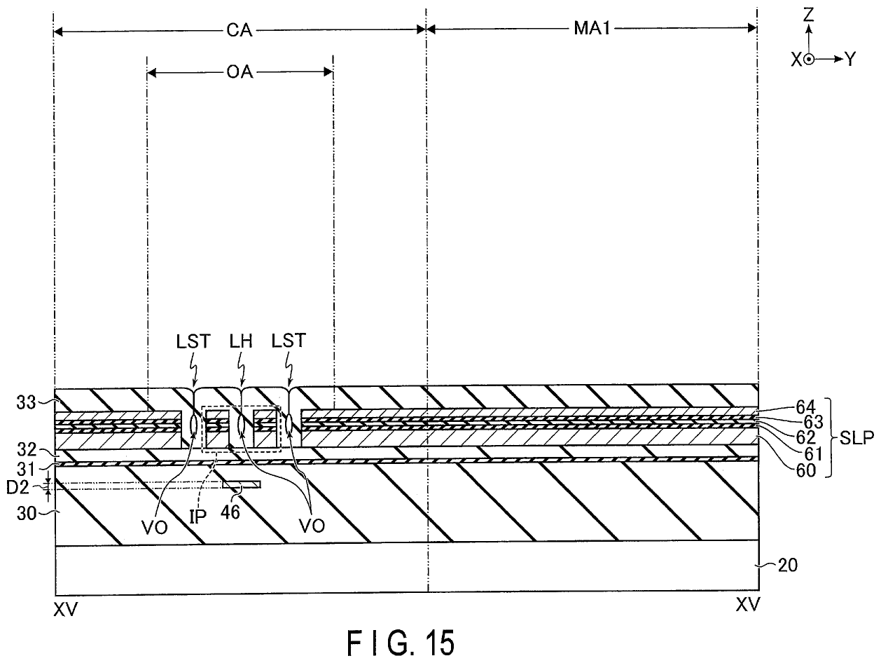

Next, as shown in FIG. 14, the insulating layer 33 is formed sous to have a void VO in each of the slits LST and holes LH (step S12). Specifically, the insulating layer 33 (e.g., a silicon oxide film) is formed by using a plasma chemical vapor deposition (CVD) having poor coverage, etc., not a method having good coverage such as a low-pressure chemical vapor deposition (LPCVD). Thereby, each of the slits LST and holes LH is filled with the insulating layer 33 in a state where the void VO remains. The void VO within the slit LST individually surrounds each of the island portions IP. The void VO within the hole LH is provided in the middle of the island portion IP. FIG. 15 shows a cross section taken along line XV-XV in FIG. 14. As shown in FIG. 15, level difference portions formed by the slit LST and the hole LH are filled with the insulating layer 33. Then, a seam of the insulating layer 33 is formed on each of the void VO formed in the slit LST and the void VO formed in the hole LH. The hole LH is provided above the conductive layer 46. In other words, the hole LH is provided so as to overlap the conductive layer 46 in a plan view. The diameter of a bottom portion of the hole LH is designed so as to be smaller than a line width of the conductive layer 46.

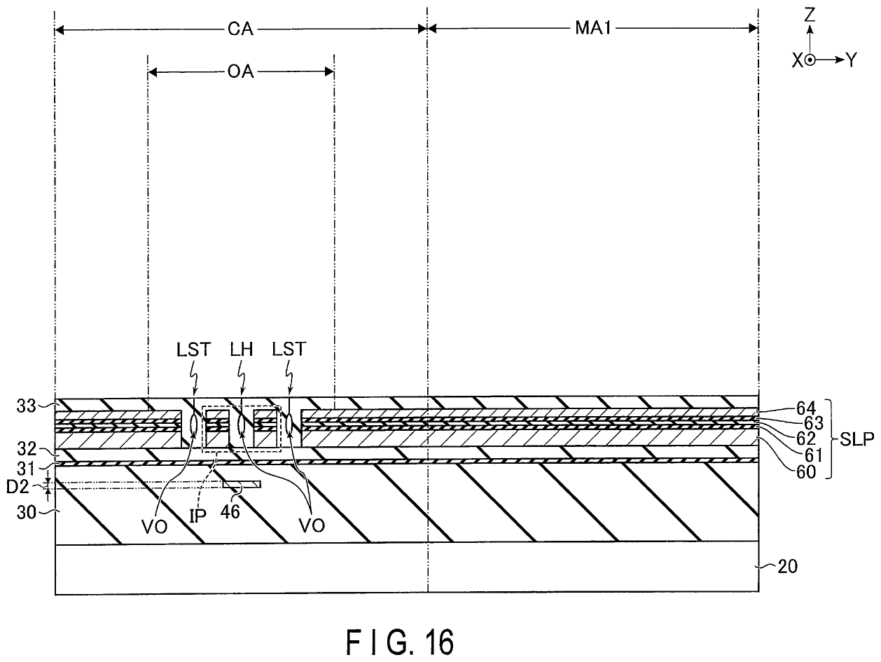

Next, as shown in FIG. 16, a planarization process of the upper surface of the insulating layer 33 is executed (step S13). In other words, level difference portions of the insulating layer 33 formed above the slit LST and the hole LH are planarized. For the planarization process of step S13, for example, an etch-back process or a chemical mechanical polishing (CMP) is used.

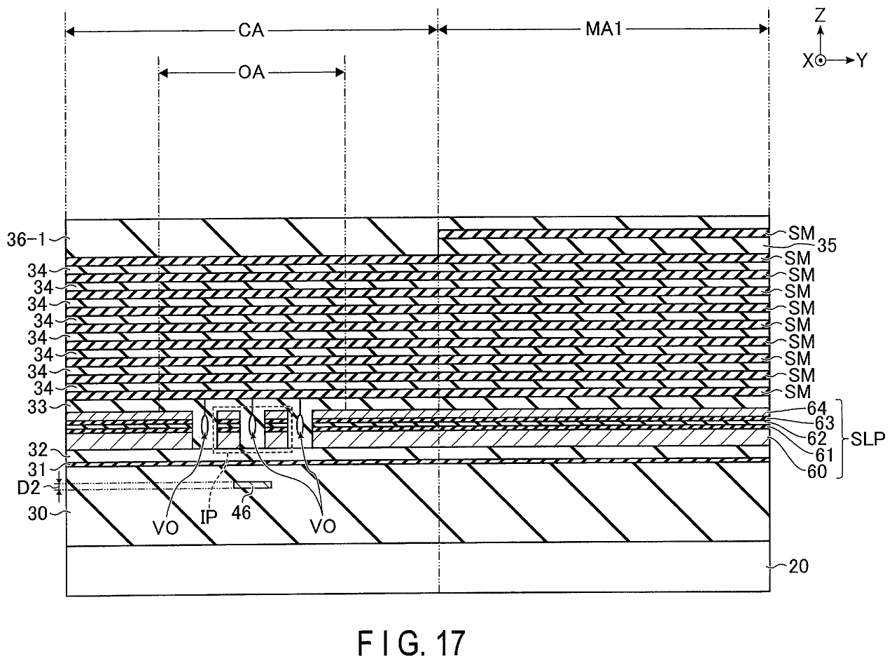

Next, as shown in FIG. 17, sacrificial members SM of the stacked interconnect portion are formed (step S14). Specifically, the sacrificial members SM and the insulating layers 34 are alternately stacked on the conductive layer 64, and the insulating layer 35 and a sacrificial member SM are stacked in this order on the uppermost sacrificial member SM. After that, by a slimming process and an etching process, for example, a staircase structure of the sacrificial members SM is formed in each of the hookup areas HA1 and HA2, and the sacrificial member SM on the insulating layer 35 and the insulating layer 35 are removed within the contact area CA. Then, a level difference formed by the formation of the staircase structure of the sacrificial members SM, etc. is filled with an insulating layer 36-1. Then, the surface of the insulating layer 36-1 is planarized by, for example, a CMP.

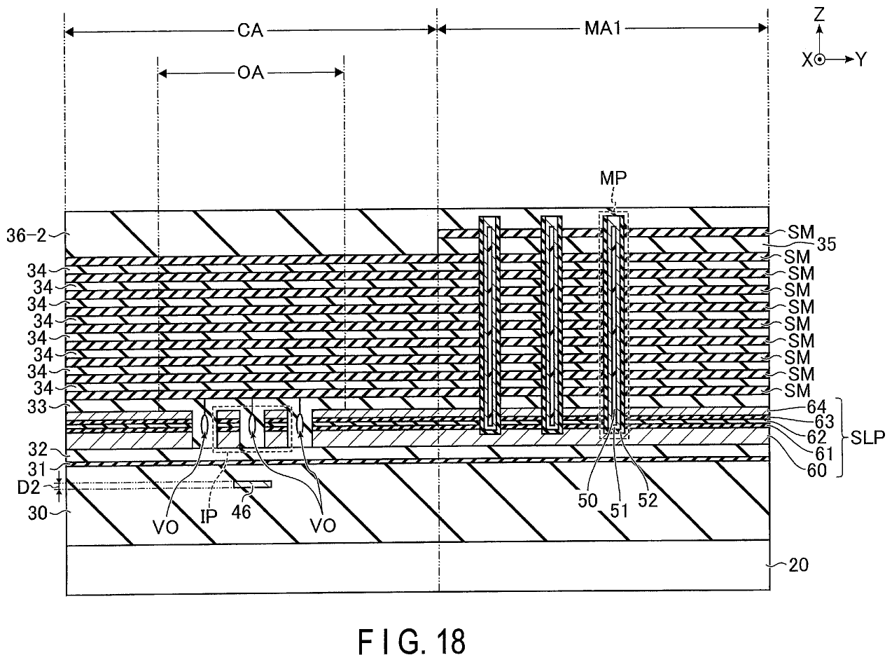

Next, as shown in FIG. 18, a memory pillar MP is formed (step S15). Specifically, first, a mask including an opening at a position corresponding to the memory pillar MP is formed by photolithography, etc. Then, by anisotropic etching using that mask, a memory hole that penetrates the insulating layer 36-1, insulating layers 35 to 33, stacked sacrificial members SM, conductive layer 64, insulating layer 63, sacrificial member 62, and insulating layer 61 is formed, and a part of the conductive layer 60 is exposed at the bottom portion of the memory hole. Subsequently, at the side surface and bottom surface of the memory hole, the stacked film 52 (i.e., the block insulating film 55, the insulating film 54, and the tunnel insulating film 53), the semiconductor layer 51, and the core member 50 are formed in this order. Thereafter, a part of the core member 50 provided at an upper portion of the memory hole is removed, and the semiconductor layer 51 is formed in the portion where the core member 50 is removed. After the memory pillar MP is formed in this way, a protective film covering an upper portion of the memory pillar MP is formed. FIG. 18 shows a set of that protective film and the insulating layer 36-1 as an insulating layer 36-2.

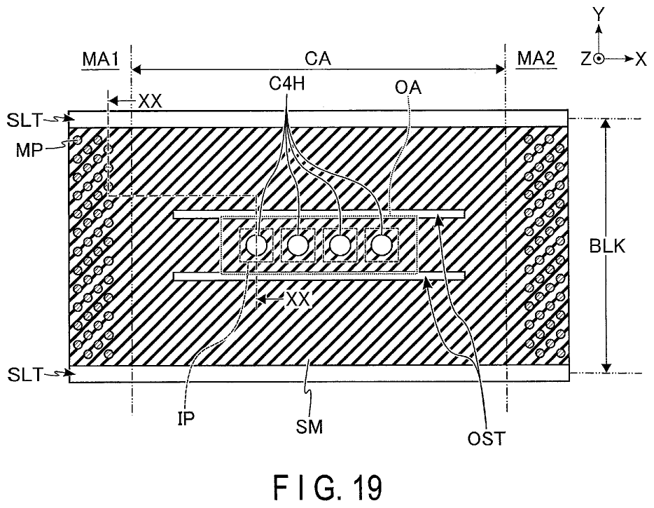

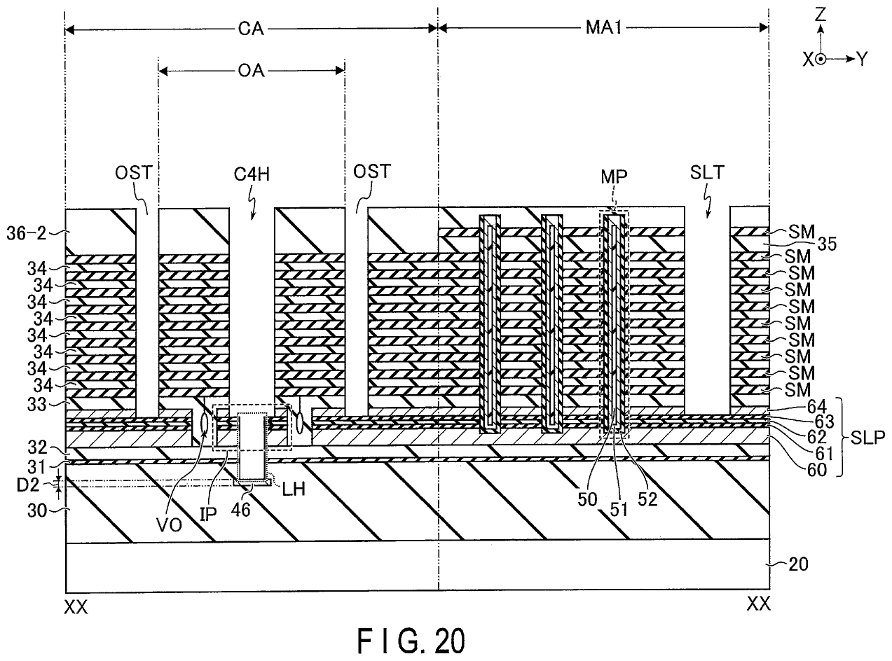

Next, the slits SLT and OST, and holes C4H, are formed (step S16). Specifically, as shown in FIG. 19, the sacrificial member SM, etc. are processed by, for example, a combination of photolithography and anisotropic etching, and the slits SLT and OST, and a plurality of holes C4H, are formed. The slit SLT is, for example, provided at a boundary portion of the blocks BLK. The two slits OST are provided so as to sandwich the penetration area OA. The holes C4H are provided so as to respectively overlap a plurality of island portions IP. FIG. 20 shows a cross section taken along line XX-XX in FIG. 19. As shown in FIG. 20, the slit SLT divides the insulating layer 36-2, insulating layers 35 to 33, stacked sacrificial members SM, and conductive layer 64, and the insulating layer 63 is exposed at the bottom portion of that slit SLT. The slit OST divides the insulating layer 36-2, insulating layers 34 and 33, stacked sacrificial members SM, and conductive layer 64, and the insulating layer 63 is exposed at the bottom portion of that slit OST. The hole C4H penetrates the insulating layer 36-2, insulating layers 34 and 33, stacked sacrificial members SM, and insulating layers 32 and 31, and the conductive layer 46 is exposed at the bottom portion of that hole C4H.

In the present example, for formation of each of the slits SLT and OST, the insulating layer 63 is used as an etching stopper. On the other hand, the etching for forming the hole C4H proceeds toward the portion of the hole LH formed in the island portion IP, that is, the portion from which the insulating layer 63 has been removed. Therefore, the processing of the hole C4H can proceed deeper than each of the slits SLT and OST along the hole LH by processing the hole C4H so that an etching rate of the insulating layer 33 is higher than that of the insulating layer 63. Then, the portion of the hole LH is filled with the insulating layer 33 including the void VO. The void VO does not interfere with etching. Therefore, when the etching for forming the hole C4H reaches the void VO, the etching of the insulating layer 33 formed under the void VO begins. As a result, the etching process in step S16 can cause the bottom of the hole C4H to reach the conductive layer 46 while suppressing overetching at the bottoms of the slits SLT and OST. A diameter of an upper portion of the hole C4H (the portion above the source line portion SLP) is based on the shape of the mask used for forming the hole C4H. On the other hand, a diameter of a lower portion of the hole C4H (the portion below the source line portion SLP) is based on the shape of the upper portion of the hole LH.

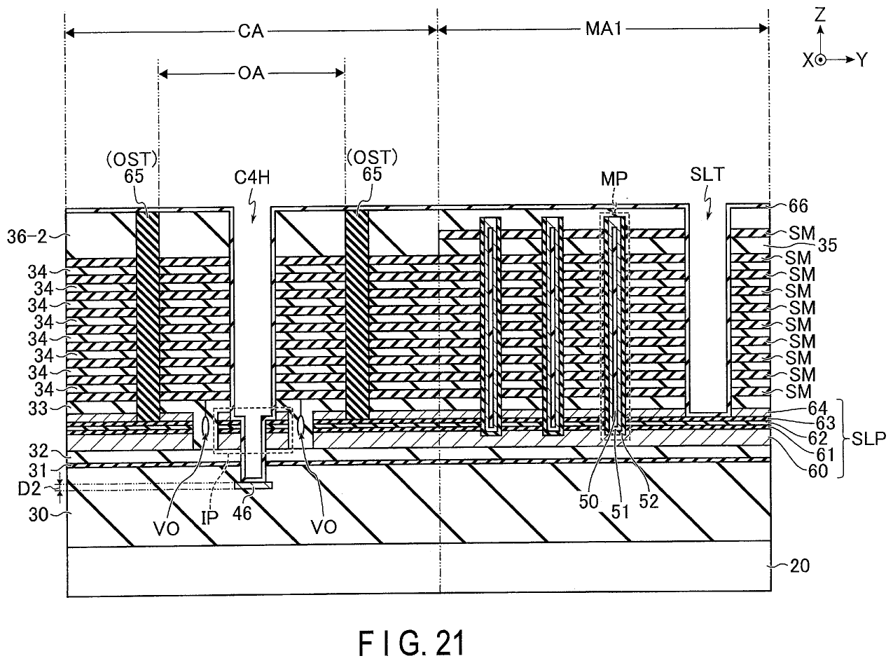

Next, an insulator 65 is formed in the slits OST (step S17). Specifically, for example, the insulator 65 is formed in a state where the slit SLT and the hole C4H are masked, and the inside of the slits OST is filled. Then, the mask and the insulator 65 provided outside the slit OST are removed. After that, as shown in FIG. 21, a protective film 66 for the subsequent replacement process is formed. The protective film 66 is provided so as to cover at least the side surface and the bottom surface of the hole C4H and the side surface and the bottom surface of the slit SLT.

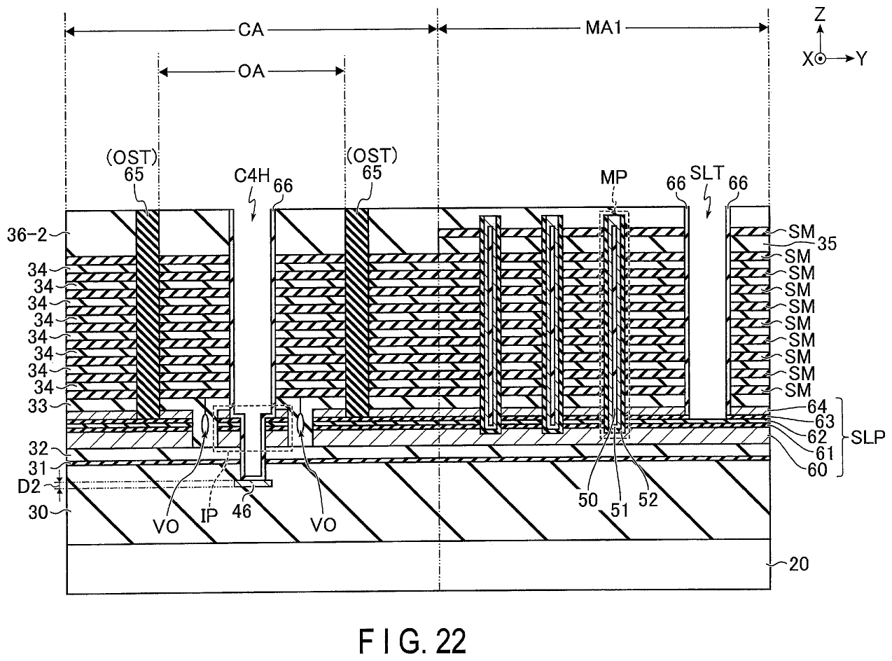

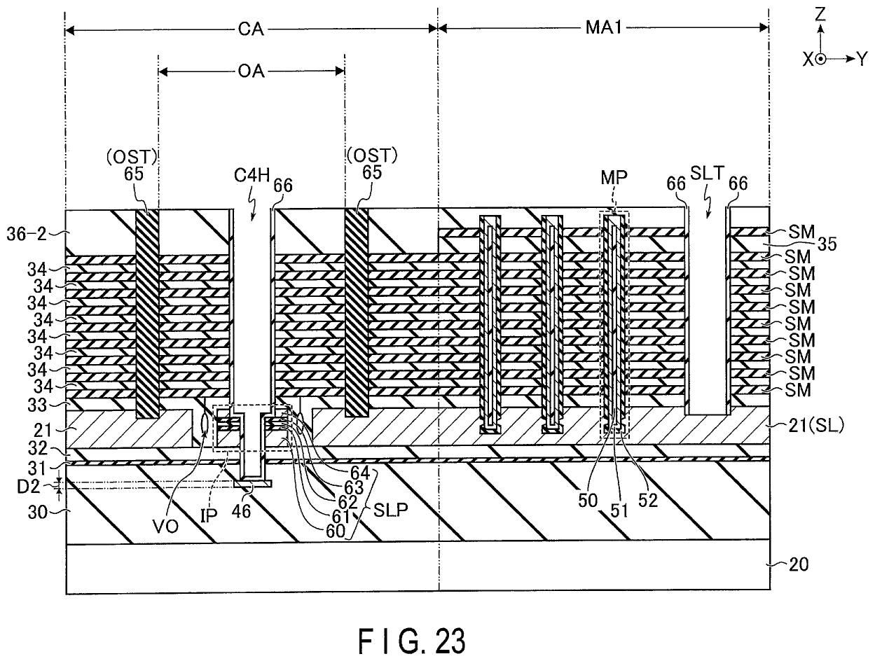

Next, a replacement process of the source line portion SLP is executed (step S18). Specifically, first, as shown in FIG. 22, the protective film 66 and the insulating layer 63 provided at the bottom of the slit SLT are removed, and the sacrificial member 62 is exposed at the bottom of the slit SLT. At this time, it suffices that the protective film 66 remains at least on the side surfaces of the hole C4H and the slit SLT. Then, by wet etching, for example, the sacrificial member 62 is selectively removed via the slit SLT. Subsequently, by wet etching, for example, the insulating layers 61 and 63 of the source line portion SLP and a part of the stacked film 52 on the side surface of the memory pillar MP are selectively removed via the slit SLT. Then, a conductor (e.g., silicon) is embedded in a space formed in the source line portion SLP. By that conductor and the conductive layers 60 and 64, the conductive layer 21 is formed as shown in FIG. 23, and the conductive layer 21 and the semiconductor layer 51 in the memory pillar MP are electrically coupled to each other. In the present example, the protective film 66 is removed after the replacement process of the source line portion SLP. In the source line portion SLP of the island portion IP, a path of the replacement process via the slit SLT is divided by the insulating layer 33. Therefore, after the process of step S18, the sacrificial member 62 and the insulating layers 61 and 63 remain without being replaced by the conductor.

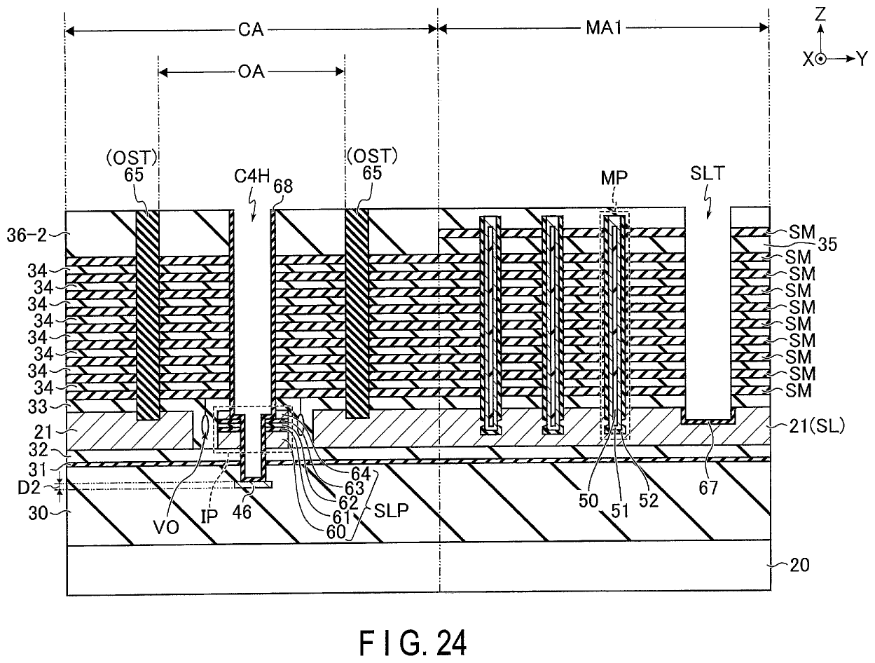

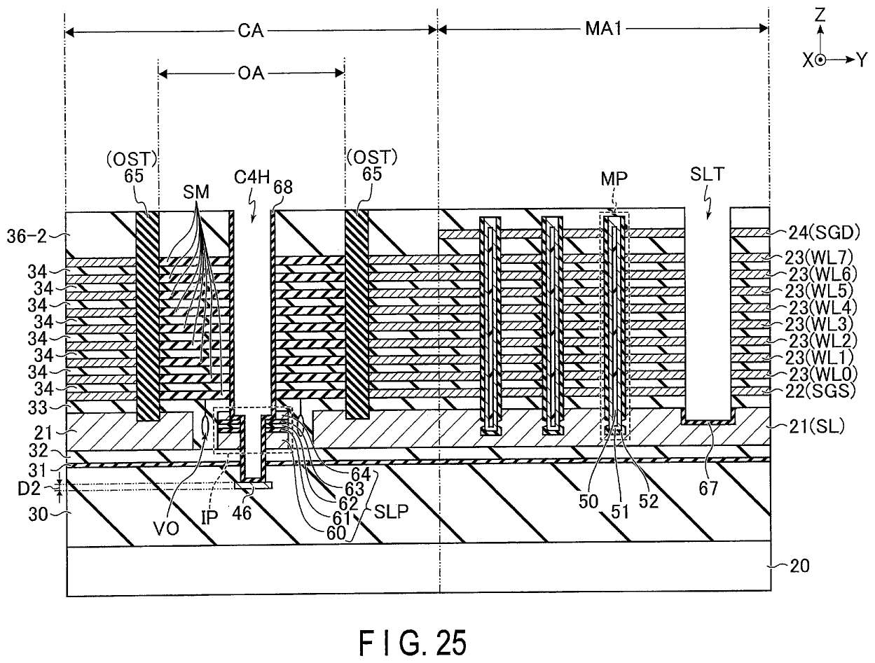

Next, a replacement process of the stacked interconnect portion is executed (step S19). First, as shown in FIG. 24, a protective film 67 (e.g., a silicon oxide film) is formed at the portion of the conductive layer 21 exposed at the bottom of the slit SLT. Further, a protective film 68 is formed on the side surface and the bottom surface of the hole C4H. Then, the stacked sacrificial members SM are selectively removed via the slit SLT by wet etching using thermal phosphoric acid, etc. A conductor is then embedded in a space from which the sacrificial members SM have been removed via the slit SLT. For the formation of the conductor in this step, CVD (chemical vapor deposition) is used, for example. After that, the conductor formed inside the slit SLT is removed by an etch-back process, and the conductor formed in adjacent interconnect layers is separated. As a result, as shown in FIG. 25, the conductive layer 22 that functions as the select gate line SGS, the plurality of conductive layers 23 that each function as the word line WL, and the conductive layer 24 that functions as the select gate line SGD are formed. In the present example, the protective film 68 is removed after the replacement process of the stacked interconnect portion. The conductive layers 22 to 24 formed in this step may contain a barrier metal. In this case, in the formation of the conductor after the removal of the sacrificial members SM, tungsten is formed after, for example, a titanium nitride film is formed as a barrier metal. During the wet etching in step S19, a chemical solution such as thermal phosphoric acid does not reach the penetration area OA. Thus, after the process of step S19, the plurality of sacrificial members SM provided within the penetration area OA remain without being replaced by the conductor.

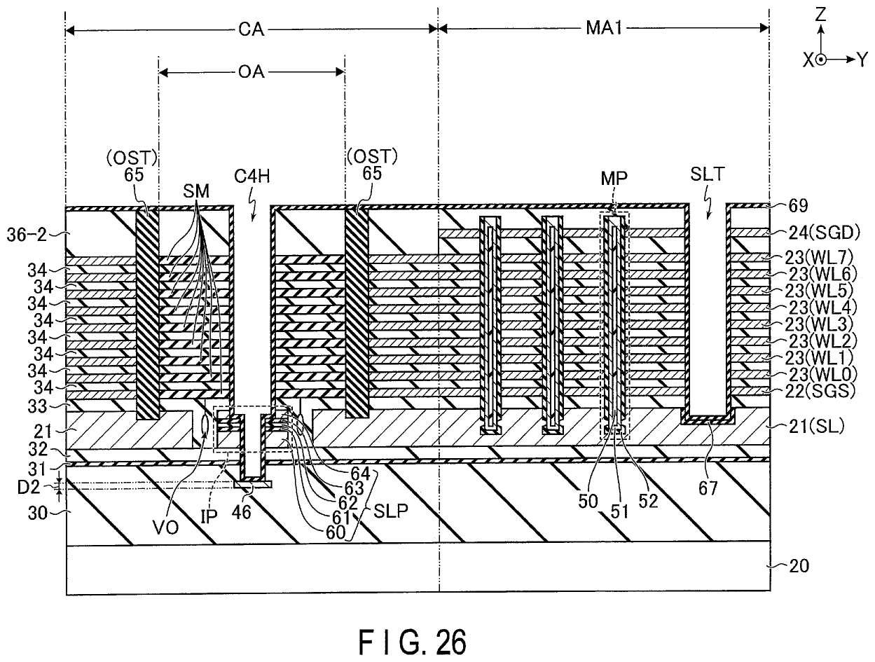

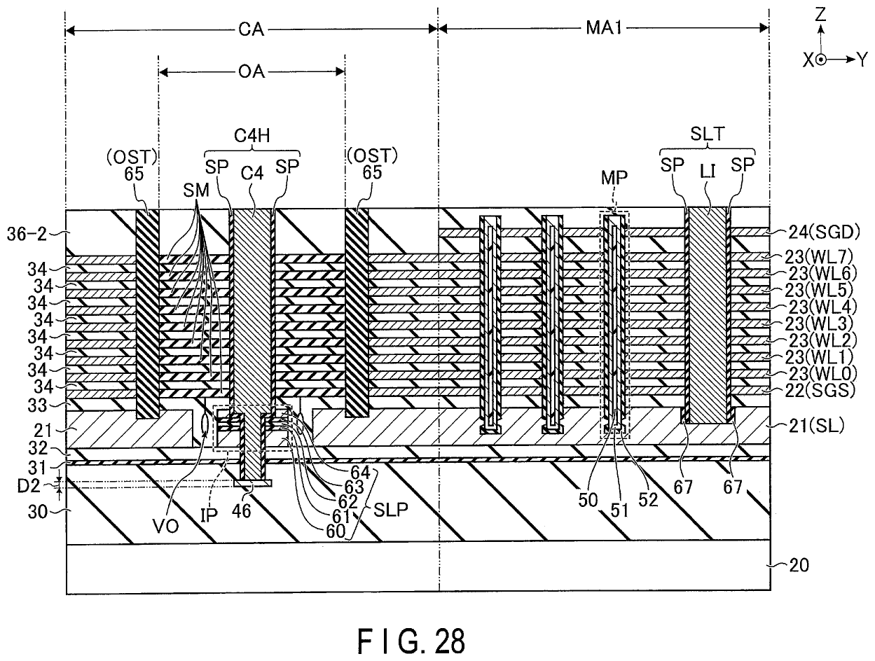

Next, a spacer SP and a contact LI are formed inside the slit SLT, and a spacer SP and a contact C4 are formed inside the hole C4H (step S20). Specifically, as shown in FIG. 26, first, an insulating film 69 corresponding to the spacer SP is formed by CVD, etc. The insulating film 69 is formed not only on the side surfaces but also on the bottom surfaces of the slit SLT and the hole C4H. Subsequently, by an etch-back process, the insulating film 69 and the protective film 67 formed at the bottom of the slit SLT are removed, and the insulating film 69 formed at the bottom of the hole C4H is removed. As a result, the conductive layer 21 is exposed at the bottom of the slit SLT, and the conductive layer 46 is exposed at the bottom of the hole C4H. Then, a conductor is embedded in each of the slit SLT and the hole C4H, and as shown in FIG. 28, the conductor formed outside the slit SLT and the hole C4H is removed.

The conductor formed inside the slit SLT corresponds to the contact LI. The conductor formed inside the hole C4H corresponds to the contact C4. After that, when an insulating layer is formed on the insulating layer 36-2, the insulating layer 36 shown in FIG. 9 is formed.

As described above, the respective spacers SP of the contacts C4 and LI are formed by the same step S20. Therefore, a composition and a film thickness of the spacer SP provided on the side surface of the contact C4 and those of the spacer SP provided on the side surface of the contact LI are approximately the same. Similarly, compositions of the contacts C4 and LI are approximately the same.

### [3] Advantageous Effect of Embodiment

According to the semiconductor memory device 1 according to the embodiment described above, the chip area of the semiconductor memory device 1 can be suppressed. Details of the advantageous effect of the semiconductor memory device 1 according to the embodiment will be described below.

In order to reduce the manufacturing cost of a semiconductor memory device, it is preferable to integrate manufacturing steps as much as possible. For example, steps of processing the slit SLT and the hole C4H can be integrated. However, a processing depth of the slit SLT and that of the hole C4H are different, and the processing depth of the hole C4H is deeper than that of the slit SLT. In order to establish the integrated processing of the slit SLT and the hole C4H in consideration of this difference in processing depth, for example, it is conceivable to increase the diameter of the opening portion of the mask for forming the hole C4H to increase the etching rate of that opening portion. On the other hand, when the diameter of the opening portion is increased, the diameter of the bottom portion of the hole to be formed is also increased. Thus, it is preferable to increase the line width of the conductive layer 46 of the interconnect layer D2 to which the contact C4 is coupled. Increasing the line width of the conductive layer 46 can be a factor in increasing the chip size.

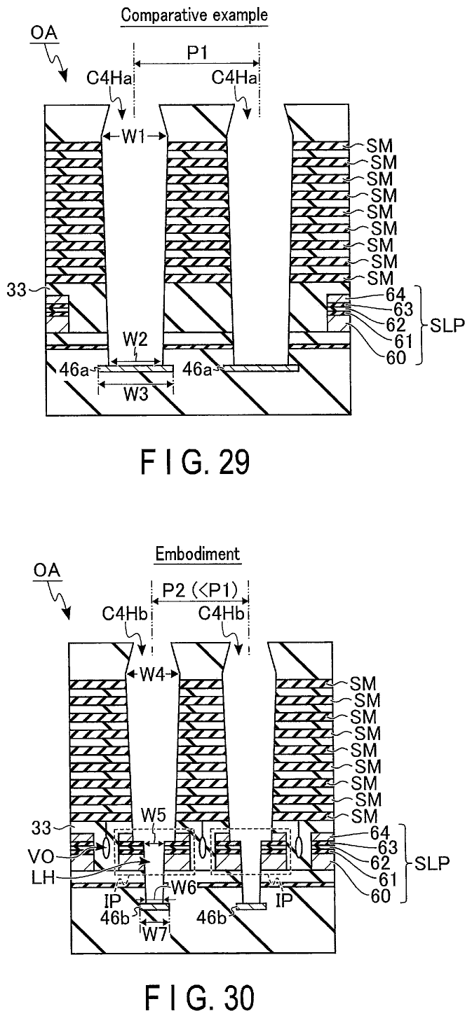

FIG. 29 is a cross-sectional view showing an example of a layout of a hole C4H in a comparative example, showing two adjacent holes C4Ha within the penetration area OA. The comparative example has a configuration in which the island portion IP is replaced with the insulating layer 33 in the penetration area OA. As shown in FIG. 29, the holes C4Ha may each have a bowed shape. When the island portion IP is not provided, a diameter W2 at a bottom portion of the hole C4Ha increases as a diameter W1 at an upper portion of the hole C4Ha increases. Further, a line width W3 of a conductive layer 46a is, for example, designed to be larger than each of the diameters W1 and W2. Then, a pitch P1 of the adjacent holes C4Ha and a line width W3 of the conductive layer 46a are each designed so that the adjacent holes C4Ha do not come into contact with each other and a predetermined margin is formed at a superposition of the conductive layer 46a and the hole C4Ha. In the comparative example, when the slit SLT and the hole C4Ha are integrally processed, the line width W3 of the conductive layer 46a is designed to be broad and the pitch P1 is designed to be large as described above.

On the other hand, in the semiconductor memory device 1 according to the embodiment, a source line portion SLP is processed before a hole C4H and a slit SLT are processed in a batch, and an insulating film (the insulating layer 33) is embedded in the processed portion by using a method having poor coverage. As a result, a ring-shaped island portion IP surrounding the insulating layer 33 having avoid VO is formed in the source line portion SLP within the contact area CA. In other words, a void VO is formed in a portion deeper than the slit SLT in a portion to be processed into the hole C4H.

FIG. 30 is a cross-sectional view showing an example of a layout of a hole C4H according to the embodiment, showing two adjacent holes C4Hb within the penetration area OA. As shown in FIG. 30, in the present example, the holes C4Hb each have a bowed shape and include a hole LH. In the embodiment, a diameter W6 of a bottom portion of the hole C4Hb is determined based on a diameter W5 of an upper portion of the hole LH, not a diameter W4 of an upper portion of the hole C4Hb. A pitch P2 of the adjacent holes C4Hb and a line width W7 of the conductive layer 46b are each designed so that the adjacent holes C4Hb do not come into contact with each other and a predetermined margin is formed at a superposition of the conductive layer 46b and the hole C4Hb. Then, in the embodiment, when the slit SLT and the hole C4Hb are integrally processed, the portion of the insulating layer 33 in which the void VO is formed is included in the etching target, so that the etching rate of that portion can be increased in a pseudo manner at the time of forming the hole C4Hb.

As a result, in the embodiment, in the integration processing of the slit SLT and the hole C4Hb, the bottom portion of the slit SLT stops in the vicinity of the conductive layer 64, and the hole C4Hb can be coupled to the conductive layer 46. Then, in the embodiment, an etching rate in the formation of the hole C4Hb can be increased without the diameter W4 of the hole C4Hb being increased. Therefore, in the semiconductor memory device 1 according to the embodiment, the diameter of the contact C4 can be reduced, the line width W7 of the conductive layer 46b can be reduced, and the pitch P2 of the conductive layer 46b can be reduced. That is, it is possible in the semiconductor memory device 1 according to the embodiment to reduce the layout of the contact area CA, and reduce the chip size of the semiconductor memory device 1.

In addition, the semiconductor memory device 1 according to the embodiment is capable of reducing the area of the source line portion SLP processed to remove in step S11 by forming a plurality of island portions IP. The area of the source line portion. SLP to be processed is reduced so that an occurrence of dishing, etc. in the planarization process after the insulating layer 33 is embedded can be suppressed as compared to the comparative example. As a result, it is possible in the semiconductor memory device 1 according to the embodiment to suppress in the sacrificial members SM stacked in the upper portion of the penetration area OA generation of undulation, etc. caused by the base (the processed source line portion SLP) as compared to the comparative example. That is, the semiconductor memory device 1 according to the embodiment is capable of enhancing the flatness of the stacked interconnect portion and suppressing an occurrence of defects caused by undulation, etc. of the stacked interconnect portion.

### [4] Modifications, etc.

The semiconductor memory device 1 according to the embodiment described above can be variously modified.

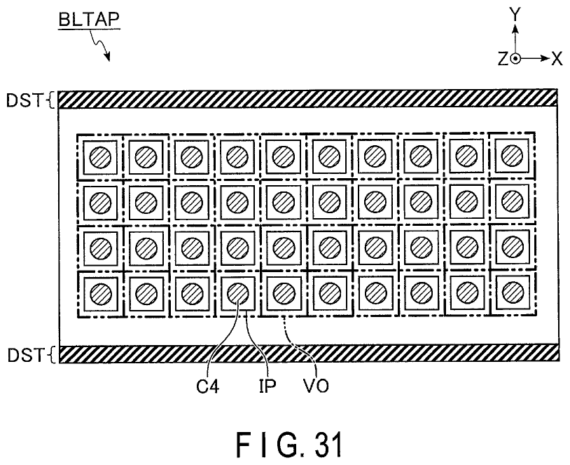

For example, the island portion IP may be provided in the bit line coupling area BLTAP. FIG. 31 is a plan view showing an example of a planar layout in the bit line coupling area BLTAP of the memory cell array 10 included in the semiconductor memory device 1 according to the embodiment. As shown in FIG. 31, the bit line coupling area BLTAP includes, for example, a region sandwiched between two dummy slits DST. The dummy slits DST each have the same shape as that of the slit SLT, and have a structure in which an insulator is embedded. The dummy slits DST are not used as paths for etching the sacrificial members SM at the time of the replacement process. Thus, in the bit line coupling area BLTAP, the sacrificial members SM of the stacked interconnect portion remain in the same manner as in the penetration area OA. Then, in the present example, a plurality of island portions IP are arranged in a staggered manner in the region sandwiched between the dummy slits DST. In each of the island portions IP, a contact C4 is provided so as to penetrate in the same manner as in the embodiment. In addition, each of the island portions IP is divided and separated by the insulating layer 33 including a void VO. As such, in a case where the island portions IP are provided in the bit line coupling area BLTAP as well, the same effect as that of the embodiment can be realized. The configuration of the bit line coupling area BLTAP may be other configurations, and it suffices that at least a plurality of contacts C4 are provided so as to penetrate the island portions IP.

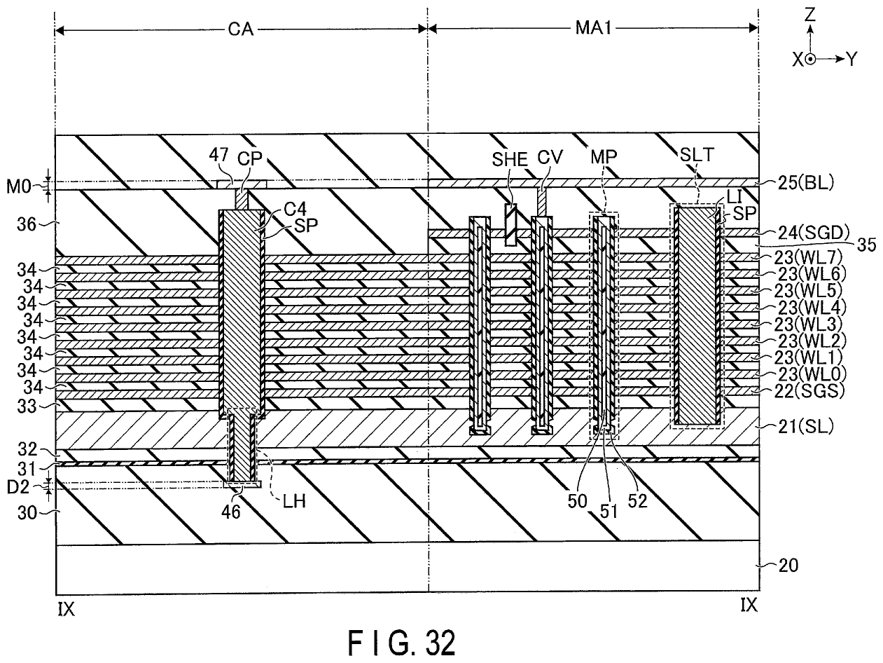

If it is possible to insulate the contacts C4 and the word lines WL, etc. provided in the stacked interconnect portion by the spacer SP, the slits OST and LST within the contact area CA may be omitted. FIG. 32 is a cross-sectional view showing an example of a cross-sectional structure in a contact area CA of a memory cell array 10 included in a semiconductor memory device 1 according to a modification of the embodiment. As shown in FIG. 32, all the sacrificial members SM within the contact area CA may be replaced by a conductor, and all the source line portions SLP within the contact area CA may be replaced by the conductive layer 21. In addition, only one of the slits OST and LST may be omitted. In a case where the slit LST is omitted, it suffices that at least a hole LH is formed and an insulating layer 33 is formed so that a void VO is provided. In such a case as well, the same effect as that of the embodiment can be obtained, and distortion of the stacked interconnect portion in the contact area CA can be suppressed. Forming the penetration area OA as described in the embodiment has an advantage wherein the contact C4 and the word lines WL, etc. can be more reliably insulated. Forming the island portion IP as described in the embodiment has an advantage wherein the contact C4 and the source line SL can be more reliably insulated. The slit LST may also be omitted in the bit line coupling area BLTAP in the same manner as in the contact area CA.

The manufacturing steps described in the embodiment are merely examples. For example, another step may be interposed between manufacturing steps, and the order of the manufacturing steps may be altered unless a problem occurs. The number of interconnect layers described in the embodiment is merely an example. It suffices that one or more interconnect layers are provided between the source line SL and the semiconductor substrate 20. The memory pillar MP may have a structure in which two or more pillars are coupled in the Z direction. The memory pillar MP may have a structure in which a pillar corresponding to a select gate line SGD and a pillar corresponding to a word line WL are coupled. Any memory pillar MP and bit line EL as well as any contact C4 and conductive layer 47 may be coupled by a plurality of contacts coupled in the Z direction. A conductive layer may be inserted into a coupling portion of the contacts.

In the drawings used for descriptions in the above embodiment, a case in which the memory pillar MP has the same diameter in the Z direction has been exemplified, but the present invention is not limited thereto. For example, the memory pillar MP may have either a tapered or reverse-tapered shape, or a shape that bulges at the middle (bowed shape). Similarly, each of the slits SLT, SHE, OST, and LST may have a tapered or reverse-tapered shape, or may have a bowed shape. Similarly, each of the contacts C0 to C2, C4, CP, and CV may have a tapered or reverse-tapered shape, or may have a bowed shape. In addition, a cross-sectional structure of each of the memory pillar MP and the contact C4 may be oval, or may be freely designed.

The contact C4 inside the hole C4H and the contact LI inside the slit SLT may be formed in separate steps. In this case, the spacer SP on the side surface of the contact C4 may be omitted. In a case where the contact C4 inside the hole C4H and the contact. LI inside the slit SLT are formed in separate steps, the slit SLT may be formed of a single or a plurality of types of insulators. In this case, for example, a contact corresponding to a source line SL is provided in a hookup area HA. The island portion IP is provided as described in the embodiment so that at least distortion of the stacked interconnect portion in the contact area CA can be suppressed. In the embodiment, a position of a slit SLT can be specified based on a position of a contact LI. When a slit SLT is formed of an insulator, the position of the slit SLT can be specified based on, for example, a seam in the slit SLT and a material remaining in the slit SLT at the time of a replacement process. In the present specification, the term “diameter” indicates an inner diameter of a hole, etc. in a cross section parallel to the surface of the semiconductor substrate 20. The “diameter of a hole” may be estimated based on an outer diameter of a member embedded in that hole. The terms “width” and “line width” indicate, for example, a width of a structural element in the X direction or the Y direction. The term “couple” indicates a state of being electrically coupled, and does not exclude, for example, a coupling via another element. The term “electrically coupled” may indicate coupling via an insulator as long as the same operation as that by electrical coupling is possible. The term “columnar” indicates being a structure which is provided in a hole formed in the manufacturing step of the semiconductor memory device 1. It suffices that the term “same layer structure” means that at least the order of formation of layers is the same.

In the present specification, the term “interconnect layer” corresponds to, for example, a layer in which an interconnect used for coupling between elements is arranged. The “contact” is, for example, a member that is used for electrically coupling two interconnects provided in different interconnect layers or electrically coupling an interconnect and the semiconductor substrate 20. The “semiconductor layer” may be referred to as a “conductive layer”. The conductive layers 60 and 64 of the source line portion SLP may be referred to as source lines. In the source line portion SLP, the upper surface of the source line corresponds to the upper surface of the conductive layer 64. An “area” may be regarded as a configuration included within the semiconductor substrate 20. For example, when the semiconductor substrate 20 is defined as including a memory area MA and a hookup area HA, the memory area MA and the hookup area HA are respectively associated with different areas above the semiconductor substrate 20. The “height” corresponds to, for example, a distance in the Z direction between a measurement target configuration and the semiconductor substrate 20. As a criterion of “height”, a configuration other than the semiconductor substrate 20 may be used. The “plan view” corresponds to, for example, a state of viewing, from the Z direction, the XY plane formed of the X and Y directions.

While certain embodiments of the present invention have been described, these embodiments have been presented by way of example only, and are not intended to limit the scope of the invention. These novel embodiments may be embodied in various forms, and various omissions, replacements, and changes can be made thereon without departing from the spirit of the invention. These embodiments and modifications thereof are included in the scope and spirit of the invention, and are also included in the invention described in the claims and their equivalents.

1. A semiconductor memory device comprising:
a substrate;
a lower interconnect provided above the substrate;
a source line provided in a first layer above the lower interconnect;
a plurality of word lines provided above the source line, the word lines being separated from one another in a first direction intersecting a surface of the substrate;
a pillar provided to extend in the first direction and penetrate the word lines, a bottom portion of the pillar reaching the source line, and intersecting portions of the pillar and the word lines respectively functioning as memory cells;
a pattern portion provided to be separated and insulated from the source line in the first layer; and
a contact extending in the first direction, penetrating the pattern portion, and provided on the lower interconnect, wherein
a width of the contact in a second direction parallel to the surface of the substrate differs between a portion above a boundary plane that is included in the first layer and is parallel to the surface of the substrate, and a portion below the boundary plane.

2. The device of claim 1, wherein
the width of the contact in the second direction discontinuously changes at the boundary plane, and is smaller at the portion below the boundary plane than at the portion above the boundary plane.

3. The device of claim 1, further comprising:
a first insulating layer including a first portion and a second portion, the first portion of the first insulating layer being provided in the first layer and surrounding the pattern portion in a plan view, and the second portion of the first insulating layer being provided on the source line, wherein
the first portion of the first insulating layer includes a void.

4. The device of claim 3, wherein
the void surrounds the pattern portion in the plan view.

5. The device of claim 3, wherein
the pattern portion comprises a plurality of pattern portions provided in the first layer, and
adjacent pattern portions of the pattern portions are separated and insulated by the first insulating layer.

6. The device of claim 1, further comprising:
a source line contact dividing the word lines and provided on the source line, the source line contact including a portion extending in the first direction and a third direction intersecting the first direction, wherein
a height of an upper end of the contact and a height of an upper end of the source line contact are approximately equal.

7. The device of claim 6, further comprising:
a first insulating film provided on a side surface of the contact; and
a second insulating film provided on a side surface of the source line contact, wherein
compositions of the contact and the source line contact are approximately identical, and
compositions and film thicknesses of the first insulating film and the second insulating film are approximately identical.

8. The device of claim 6, wherein
the substrate includes a first area and a second area arranged in the third direction,
the pillar is included in the first area, and
the contact is included in the second area.

9. The device of claim 6, further comprising:
a plurality of sacrificial members respectively provided at identical heights to the word lines above the pattern portion, the sacrificial members being surrounded by the word lines in a plan view, wherein
the contact penetrates the sacrificial members.

10. The device of claim 9, further comprising:
a first insulating member and a second insulating member arranged in a fourth direction intersecting the first and third directions, wherein each of the first insulating member and the second insulating member includes a portion extending in the first and third directions and is provided in contact with each of the word lines and the sacrificial members between the word lines and the sacrificial members, and a bottom portion of each of the first insulating member and the second insulating member reaches the first layer.

11. The device of claim 10, wherein
heights of upper ends of the contact, the source line contact, the first insulating member, and the second insulating member are approximately identical.

12. The device of claim 6, further comprising:
a bit line provided to extend in a fourth direction intersecting the first and third directions above the word lines, the bit line being electrically coupled to the pillar, wherein
the substrate includes a third area and a fourth area arranged in the fourth direction,
the pillar is included in the third area,
the contact is included in the fourth area, and
the bit line and the contact are electrically coupled.

13. The device of claim 1, wherein
the pattern portion has a stacked structure including a first conductive layer, a second conductive layer, and a second insulating layer provided between the first conductive layer and the second conductive layer, and
a height of a lower surface of the first conductive layer is approximately identical to a height of a lower surface of the source line.

14. The device of claim 13, wherein
a height of an upper surface of the second conductive layer is approximately identical to a height of an upper surface of the source line.

15. The device of claim 13, wherein
the pillar includes a semiconductor layer and a third insulating film, the semiconductor layer being provided to extend in the first direction, and the third insulating film being provided between the semiconductor layer and the word lines, and
the semiconductor layer and the source line are in contact with each other via a side surface of the pillar.

16. A semiconductor memory device comprising:
a substrate;
a lower interconnect provided above the substrate;
a source line provided above the lower interconnect;
a plurality of word lines provided above the source line, the word lines being separated from one another in a first direction intersecting a surface of the substrate;
a pillar provided to extend in the first direction and penetrate the word lines, a bottom portion of the pillar reaching the source line, and intersecting portions of the pillar and the word lines respectively functioning as memory cells;
a contact extending in the first direction, penetrating the source line, and provided on the lower interconnect; and
a first insulating film provided on a side surface of the contact, the first insulating film insulating the contact from the source line, wherein
a width of the contact in a second direction parallel to the surface of the substrate differs between a portion above a boundary plane that is included in a layer in which the source line is provided and is parallel to the surface of the substrate, and a portion below the boundary plane.

17. The device of claim 16, wherein
the width of the contact in the second direction discontinuously changes at the boundary plane, and is smaller at the portion below the boundary plane than at the portion above the boundary plane.

18. The device of claim 16, further comprising:
a source line contact dividing the word lines and provided on the source line, the source line contact including a portion extending in the first direction and a third direction intersecting the first direction, wherein
a height of an upper end of the contact and a height of an upper end of the source line contact are approximately equal.

19. The device of claim 18, further comprising:
a second insulating film provided on a side surface of the source line contact, wherein
compositions of the contact and the source line contact are approximately identical, and
compositions and film thicknesses of the first insulating film and the second insulating film are approximately identical.

20. The device of claim 18, wherein
the substrate includes a first area and a second area arranged in the third direction,
the pillar is included in the first area, and
the contact is included in the second area.
